(19) United States
(12) Patent Application Publication
(10) Pub. No.: US 2016/0079233 A1
(43) Pub. Date: Mar. 17, 2016

(54) III-V SEMICONDUCTOR MATERIAL BASED AC SWITCH

(71) Applicant: Infineon Technologies Austria AG, Villach (AT)

(72) Inventors: Gerald Deboy, Klagenfurt (AT); Gilberto Curatola, Villach (AT)

(21) Appl. No.: 14/486,260

(22) Filed: Sep. 15, 2014

(51) Int. Cl. H01L 27/06; H03K 17/725; H01L 29/872; H01L 29/20; H01L 29/778; H01L 29/205

(52) U.S. Cl. CPC H01L 27/0629; H01L 29/7787; H01L 29/205; H01L 29/872; H01L 29/2003; H03K 17/725; H03K 2217/0009

(57) ABSTRACT

A power circuit is described that includes a semiconductor die and a coupling structure. The semiconductor die includes a common substrate and a III-V semiconductor layer formed atop the common substrate. At least one bidirectional switch device is formed at least partially within the III-V semiconductor layer. The at least one bidirectional switch has at least a first load terminal and a second load terminal. The coupling structure is configured to dynamically couple the common substrate of the semiconductor die to a lowest potential out of a first potential of the first load terminal and a second potential of the second load terminal.

### BACKGROUND

A III-V compound is a compound formed by combining elements from group III and group V of the Periodic Table of Elements. Group III elements include Boron (B), Aluminum (Al), Gallium (Ga), Indium (In), and Titanium (Ti). Group V elements include Nitrogen (N), Phosphorous (P), Arsenic (As), Antimony (Sb), and Bismuth (Bi).

III-V compounds, such as Gallium Nitride (GaN), are sometimes used as a fabrication material for semiconductor devices. For example, a III-V semiconductor based semiconductor device may be a semiconductor device formed at least partially within a layer of GaN or layer of other III-V semiconductor material, that is disposed atop a substrate (e.g., a Silicon (Si) substrate, a Silicon-Carbide (SiC) substrate, or other similar type of substrate made from a material that exhibits similar electrical and chemical properties as Si or SiC) of a semiconductor die.

One of the primary advantages of using III-V semiconductor materials, such as GaN, in semiconductor device fabrication is that III-V semiconductor materials have a strain-induced piezo-electric charge characteristic that allows conduction channels (e.g., two-dimensional electron gas regions [2DEG]), which have an inherently low on-resistance (R_{DSON}) to form within the III-V semiconductor material layer without doping the III-V semiconductor material layer. By eliminating the need for doping of the III-V semiconductor material layer, the overall impurity scattering effect associated with a III-V semiconductor material based semiconductor device is lower thus allowing intrinsic carrier mobilities to form more easily in the current conducting channels as compared to other semiconductor devices.

Unfortunately, III-V semiconductor material layers are susceptible to “traps.” Traps are regions that can form in III-V semiconductor material due to a potentially large band gap associated with III-V semiconductor material. Rather than allow mobile carriers to travel through adjacent current conducting channels, III-V semiconductor layers have a tendency to cause “current collapse” at the current conducting channels by trapping or pulling mobile carriers out of the current conducting channel and retaining the mobile carriers within the traps of the III-V semiconductor layer. The R_{DSON} of a semiconductor device is directly proportionate to its trap rate and amount of current collapse. For example, current collapse may cause a III-V semiconductor based semiconductor device to have an increase in its nominal R_{DSON} by a factor of one hundred. A III-V semiconductor based semiconductor device, especially a GaN based semiconductor device, that is formed at least partially within a III-V semiconductor layer that is disposed atop a substrate of a semiconductor body, may have an abnormally higher rate of traps than other semiconductor devices. The resulting high R_{DSON} may render such a III-V semiconductor based semiconductor device unusable for some, if not all, High Electron Mobility Effect Transistor (HEMT) applications.

### SUMMARY

In general, circuits and techniques of this disclosure may enable the dynamic configuration of a semiconductor die so as to prevent current collapse in a layer of III-V semiconductor material that is formed atop a single, common substrate and allow the semiconductor die to support the formation and integration of multiple III-V semiconductor based semiconductor devices (e.g., for use as a bidirectional switch) at least partially within the III-V semiconductor layer for powering an AC load. A coupling structure (e.g., as an external component of the semiconductor die or integrated onto the die itself) may ensure that the common substrate of the semiconductor die is coupled to a lowest available potential (e.g., a lowest potential load terminal of the bidirectional switch). By ensuring that the potential of the common substrate is at or approximately at the same potential (e.g., within a few volts) as the lowest available potential, even as the location of the lowest available potential changes, the coupling structure dynamically configures the semiconductor die to repel mobile carriers, which are traveling within the conduction channel, away from the traps of the III-V semiconductor layer.

In one example, a power circuit includes a semiconductor die that includes a common substrate and a III-V semiconductor layer formed atop the common substrate. At least one bidirectional switch device is formed at least partially within the III-V semiconductor layer, and the at least one bidirectional switch comprises at least a first load terminal and a second load terminal. The power circuit further includes a coupling structure configured to dynamically couple the common substrate of the semiconductor die to a lowest potential out of a first potential of the first load terminal and a second potential of the second load terminal.

In another example, a semiconductor die includes a common substrate and a III-V semiconductor layer formed atop the common substrate. The semiconductor die also includes a bidirectional switch device formed at least partially within the III-V semiconductor layer, the bidirectional switch device having at least a first load terminal and a second load terminal. The semiconductor die also includes a coupling structure configured to dynamically couple the common substrate to a lowest potential out of a first potential of the first load terminal and a second potential of the second load terminal.

In another example, a method includes operating a semiconductor die that includes a common substrate and a III-V semiconductor layer formed atop the common substrate, wherein at least one bidirectional switch device is formed at least partially within the III-V semiconductor layer, the at least one bidirectional switch having at least a first load terminal and a second load terminal. The method further includes dynamically coupling the common substrate of the semiconductor die to a lowest potential out of a first potential of the first load terminal and a second potential of the second load terminal.

The details of one or more examples are set forth in the accompanying drawings and the description below. Other features, objects, and advantages of the disclosure will be apparent from the description and drawings, and from the claims.

### BRIEF DESCRIPTION OF DRAWINGS

FIGS. 1-3 are block diagrams illustrating example systems for powering an AC load, in accordance with one or more aspects of the present disclosure.

FIGS. 4A and 4B are circuit diagrams illustrating example MOSFET type AC switches of the example systems shown in FIGS. 1-3.

FIGS. 5A-5C are circuit diagrams illustrating example III-V semiconductor based AC switches of the example systems shown in FIGS. 1-3.

FIG. 6 is a cross sectional layered view of an example III-V semiconductor based AC switch.

FIGS. 7A and 7B are circuit diagrams illustrating example power circuits for dynamically configuring a III-V semiconductor based AC switch, in accordance with one or more aspects of the present disclosure.

FIG. 8A is a timing diagram illustrating voltage characteristics of the power circuit shown in FIG. 7A.

FIG. 8B is a timing diagram illustrating voltage characteristics of the power circuit shown in FIG. 7B.

FIG. 9A is a cross sectional layered view of an example semiconductor die that includes an example of the coupling structure of FIG. 7A laterally integrated with an example bidirectional III-V semiconductor based switch that shares the same structure as the example III-V semiconductor based AC switch shown of FIG. 5A.

FIG. 9B is a conceptual diagram illustrating an example bonding option for the example semiconductor die shown in FIG. 9A.

FIG. 10 is a cross sectional layered view of an example semiconductor die that includes an additional example of the coupling structure of FIG. 7A laterally integrated with an example bidirectional III-V semiconductor based switch that shares the same structure as the example III-V semiconductor based AC switch shown of FIG. 5A.

FIGS. 11A and 11B are cross sectional layered views of example semiconductor dies that include additional examples of the coupling structure of FIG. 7A laterally integrated with an example bidirectional III-V semiconductor based switch that shares the same structure as the example III-V semiconductor based AC switch shown of FIG. 5A.

FIG. 11C is a circuit diagram illustrating an example element of the additional examples of the coupling structure of FIGS. 11A and 11B.

FIG. 12 is a cross sectional layered view of an example semiconductor die that includes an example of the coupling structure of FIG. 7A laterally integrated with an example bidirectional III-V semiconductor based switch that shares the same structure as the example III-V semiconductor based AC switch shown of FIG. 5B.

FIG. 13 is a cross sectional layered view of an example semiconductor die that includes an additional example of the coupling structure of FIG. 7A laterally integrated with an example bidirectional III-V semiconductor based switch that shares the same structure as the example III-V semiconductor based AC switch shown of FIG. 5B.

FIGS. 14A and 14B are cross sectional layered views of example semiconductor dies that include additional examples of the coupling structure of FIG. 7A laterally integrated with an example bidirectional III-V semiconductor based switch that shares the same structure as the example III-V semiconductor based AC switch shown of FIG. 5B.

FIG. 15 is a cross sectional layered view of an example semiconductor die that includes an example of the coupling structure of FIG. 7A laterally integrated with an example bidirectional III-V semiconductor based switch that shares the same structure as the example III-V semiconductor based AC switch shown of FIG. 5C.

FIG. 16 is a cross sectional layered view of an example semiconductor die that includes an additional example of the coupling structure of FIG. 7A laterally integrated with an example bidirectional III-V semiconductor based switch that shares the same structure as the example III-V semiconductor based AC switch shown of FIG. 5C.

FIGS. 17A and 17B are cross sectional layered views of example semiconductor dies that include additional examples of the coupling structure of FIG. 7A laterally integrated with an example bidirectional III-V semiconductor based switch that shares the same structure as the example III-V semiconductor based AC switch shown of FIG. 5C.

FIG. 18 is a cross sectional layered view of an example semiconductor die that includes an example of the coupling structure of FIG. 7B laterally integrated with an example bidirectional III-V semiconductor based switch that shares the same structure as the example III-V semiconductor based AC switch shown of FIG. 5A.

FIG. 19 is a cross sectional layered view of an example semiconductor die that includes an additional example of the coupling structure of FIG. 7B laterally integrated with an example bidirectional III-V semiconductor based switch that shares the same structure as the example III-V semiconductor based AC switch shown of FIG. 5B.

FIG. 20 is a cross sectional layered view of an example semiconductor die that includes an additional example of the coupling structure of FIG. 7B laterally integrated with an example bidirectional III-V semiconductor based switch that shares the same structure as the example III-V semiconductor based AC switch shown of FIG. 5C.

FIG. 21 is a flow chart illustrating example operations of the example power circuit shown in FIG. 7B, in accordance with one or more aspects of the present disclosure.

### DETAILED DESCRIPTION

Some electrical devices (e.g., transistors, diodes, switches, and the like) are semiconductor based, or in other words, formed on semiconductor dies made from semiconductor materials. In some applications, III-V compounds are used as a fabrication material for semiconductor devices. III-V compounds are formed by combining elements from group III and group V of the Periodic Table of Elements. Examples of III-V compounds include Boron Nitride (BN), Boron Phosphide (BP), Boron Arsenide (BAs), Aluminum Nitride (AlN), Aluminum Phosphide (AlP), Aluminum Arsenide (AlAs), Aluminum Antimonide (AlSb), Gallium Nitride (GaN), Gallium Phosphide (GaP), Gallium Arsenide (GaAs), Gallium Antimonide (GaSb), Indium Nitride (InN), Indium Phosphide (InP), Indium Arsenide (InAs), Indium Antimonide (InSb), Titanium Nitride (TiN), Titanium Phosphide (TiP), Titanium Arsenide (TiAs), and Titanium Antimonide (TiSb). Semiconductor devices that are formed using III-V semiconductor materials are referred to herein as III-V semiconductor based devices. For instance, one example of a III-V semiconductor based device is a GaN based bidirectional switch. A GaN based bidirectional may be produced from one or more GaN based devices (e.g., two GaN switches) that are formed at least partially within a layer of GaN that is layered atop a substrate, for example, made from Silicon (Si) or Silicon Carbide (SiC). The one or more GaN devices may be formed at an interface between a layer of Aluminum Gallium Nitride (AlGaN) that is layered atop the GaN layer and the conducting channel of the one or more GaN devices may sit within the portion of the GaN layer the borders or is adjacent to the AlGaN layer.

III-V semiconductor based devices, such as GaN based semiconductor devices, may have a higher degree of performance at a lower cost than other types of semiconductor devices. GaN based semiconductor devices may have high saturation velocities (e.g., 2.5×10⁷ cm/s for GaN compared to Si, 1×10⁷ cm/s) and improved breakdown field strength (e.g., 5×10⁶ V/cm (3 MV/cm) for GaN compared to Si, ˜3×10⁵ V/cm (3 MV/cm)). GaN based semiconductor devices may also have direct and large bandgaps (e.g., 3.4 eV for GaN compared to silicon 1.1 eV) allowing for lower specific on resistance (“R_{DSON}”) and a high operational temperature.

One benefit to using a layer of GaN is that GaN has a strain induced piezo-electric charge that allows conduction channels (e.g., two-dimensional electron gas (2DEG) region) to be formed within the GaN based semiconductor device without the need for doping the GaN material. Eliminating the need for doping of the GaN material, may reduce the GaN based semiconductor device's impurity scattering effect, which may allow intrinsic carrier mobilities to freely form in a current conducting channel (e.g., 2DEG region) that has a low on-resistance (R_{DSON}).

Unfortunately, GaN layers are susceptible to so-called “traps.” Traps generally refer to regions that can form in a GaN layer due to a potentially large band gap associated with GaN material. That is, a trap is a localized defect in the GaN layer, such as a carbon atom introducing an energy level which sits right between the valence and the conduction band. According to Shockley-Read-Hall statistics, such a trap is especially effective in capturing electrons if its energy level sits in the middle between valence and conduction band. Rather than allow mobile carriers to travel through current conducting channels, GaN layers have a tendency to cause “current collapse” at the current conducting channels by trapping or pulling mobile carriers from out of the current conducting channel and retaining the mobile carriers within the traps of the GaN layer. That is, when undergoing current collapse, a GaN based device may no longer support the full load current due to lack of mobile carriers moving through the conduction channel. Current collapse may lead to a significant increase of the forward voltage drop across the GaN based device (e.g., from 1 or 2V to approximately 400V).

The R_{DSON} of a semiconductor device may be adversely affected by the trapping of mobile carriers from the conduction channel. The term “dynamic R_{DSON}” describes the fact that the R_{DSON} of a device may be negatively affected by a previously applied blocking voltage; that is part of the available mobile carriers from the 2DEG are captured in traps and are very slowly released only (e.g. in the time range of ms to seconds). For example, traps can cause an increase in the nominal R_{DSON} of a III-V semiconductor based semiconductor device by a factor of one hundred. A III-V semiconductor based semiconductor device, especially a III-V semiconductor based semiconductor device that has both a III-V semiconductor layer and a Si or SiC common substrate, may have an higher rate of traps than other semiconductor devices. The resulting higher R_{DSON} caused by the higher rate of traps may render a III-V semiconductor based semiconductor unusable for some, if not all, power devices or other applications.

The same high R_{DSON} that renders a III-V semiconductor based semiconductor device unusable as a HEMT may also prevent III-V semiconductor from being used to form a lateral device structure. For example, the current collapse caused by a III-V semiconductor layer, when combined with a very high-ohmic substrate, such as Si or SiC substrates, may prevent the integration of more than one III-V semiconductor based device (e.g., switch) on a single, shared or common substrate.

Traps that are found in a III-V semiconductor layer are extremely sensitive to the voltage applied to the back-side contact of the common substrate. Especially in case of low resistive Si substrate, which are typically used for the fabrication of GaN-on-Si technology. Due to the extreme sensitivity to the voltage applies to the back-side contact of the substrate, the back-side potential is immediately transferred at the III-V semiconductor layer surface, and in some examples, may excite interaction between traps in the III-V semiconductor layer and the 2DEG region and as such, result in performance loss.

In general, circuits and techniques of this disclosure may enable the dynamic configuration of a III-V semiconductor based semiconductor die so as to prevent current collapse in its III-V semiconductor layer and allow the III-V semiconductor based semiconductor die to support lateral integration of multiple III-V semiconductor based devices (e.g., for use as a bidirectional switch or other use) on a single, common substrate, for powering an AC load. A coupling structure (e.g., configured as an internal or external component of the III-V semiconductor based semiconductor die) is used to ensure that the single, common substrate of the III-V semiconductor based semiconductor die is coupled to a lowest available potential (e.g., a lowest load terminal potential of a III-V semiconductor based bidirectional switch formed at least partially within the layer of III-V semiconductor). By ensuring that the common substrate is at least approximately at or near (e.g., minus a voltage drop across the coupling struction) the same potential as the lowest available potential, even if the location of the lowest potential changes, the coupling structure prevents current collapse in the III-V semiconductor layer by repeatedly re-configuring the III-V semiconductor based semiconductor die to repel mobile carriers, which are traveling within the conduction channel of the III-V semiconductor based semiconductor die, away from the traps of the III-V semiconductor layer.

For example, if the III-V semiconductor based semiconductor die is configured as a III-V semiconductor based bidirectional switch that has two load terminals for powering an AC load, the polarity of the voltage across the load terminals of the bidirectional switch may alternate and cause the location of the lowest potential to change. In other words, the lowest potential load terminal of the bidirectional switch may alternate, periodically between one load terminal and the other. The coupling structure, either through its own configuration or while being controlled by a controller, automatically re-configures the III-V semiconductor based semiconductor die to compensate for the change in location of the lowest potential load terminal by causing the common substrate to switch from being electrically coupled to the previous, lowest potential load terminal to being electrically coupled to the current, lowest potential load terminal.

In this way, regardless of the direction that the mobile carriers are moving within the conduction channel of the III-V semiconductor based semiconductor die, the coupling structure prevents the mobile carriers from being trapped by the III-V semiconductor layer. By supporting the integration of multiple III-V semiconductor based devices, and being operable in both AC and DC environments, a III-V semiconductor based semiconductor die according to these techniques can be used in various HEMT type and lateral device type applications that were previously off-limits to III-V semiconductor based semiconductor devices.

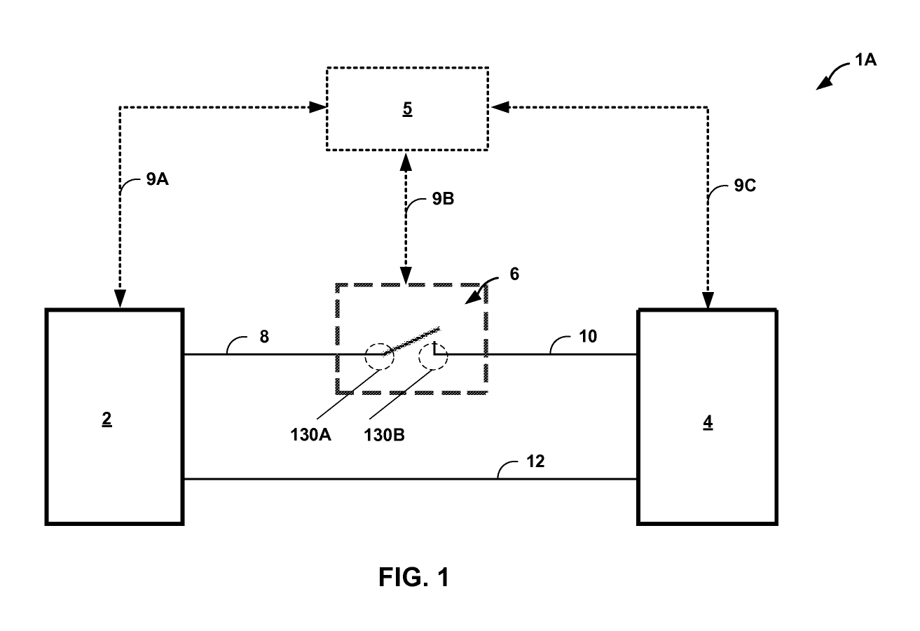

FIGS. 1-3 are block diagrams illustrating example systems 1A-1C (collectively “systems 1”) for powering AC load 4, in accordance with one or more aspects of the present disclosure. In each of the examples illustrated in FIGS. 1-3, systems 1 have multiple separate and distinct components however each of systems 1 may include additional or fewer components that provide the functionality of systems 1 as described herein.

In each of FIGS. 1-3, controller unit 5 is shown as being an optional component of systems 1. Controller unit 5 may exchange information, via links 9A-9C (collectively “links 9”), with various components of systems 1 to control the various components of systems 1. For example, AC switch 6, AC source 2, and AC load 4, may exchange information with controller unit 5 via links 9. Controller unit 5 may send one or more commands or signals via link 9B that cause AC switch 6 to open or close to control the flow of electrical energy between AC source 2 and AC load 4. Controller unit 5 may receive information via link 9B indicating the voltage and/or current level at AC switch 6. Controller unit 5 may exchange information via links 9A and 9C with AC source 2 and AC load 4, for example, for use in generating control signals or commands for controlling AC switch 6. In some examples, controller unit 5 may be electrically isolated from at least a portion of the components of system 1. For example, controller unit 5 may be electrically isolated from AC source 2, AC load 4, and/or AC switch 6 (e.g., by way of one or more opto-couplers embedded in links 9 or via other isolation techniques).

Controller unit 5 may comprise any suitable arrangement of hardware, software, firmware, or any combination thereof, to perform the techniques attributed to controller unit 5 herein, such as, but not limited to, controlling a coupling structure or driving a transistor gate of AC switch 6. For example, controller unit 5 may include any one or more drivers, microprocessors, digital signal processors (DSPs), application specific integrated circuits (ASICs), field programmable gate arrays (FPGAs), or any other integrated or discrete logic circuitry, as well as any combinations of such components. When controller unit 5 includes software or firmware, controller unit 5 further includes any necessary hardware for storing and executing the software or firmware, such as one or more processors or processing units. In general, a processing unit may include one or more microprocessors, DSPs, ASICs, FPGAs, or any other equivalent integrated or discrete logic circuitry, as well as any combinations of such components.

FIG. 1 shows system 1A which controls, via AC switch 6, the flow of (single phase) AC current traveling between AC source 2 and AC load 4 across links 8 and 10. AC source 2 and AC load 4 are connected via neutral link 12.

Numerous examples of AC source 2 exist and may include, but are not limited to, AC power grids, DC/AC power converters, transformer outputs, motors operating in an energy recuperation mode, or any other form of AC source capable of outputting an AC voltage and/or AC current for powering AC load 4.

Numerous examples of AC load 4 exist and may include, but are not limited to, AC power grids (e.g., receiving energy from a windmill, solar panel, or other renewable energy source that provides energy to the AC power grid), island AC power grids (e.g., residential homes, remote area homes, etc.), AC motors, transformer inputs (e.g., fifty Hz isolating transformers and the like), or any other type of electrical device and/or circuitry that receives an AC voltage or an AC current from an AC power source such as AC source 2.

In general, system 1A relies on AC switch 6 to operate as an intermediary device for controlling the flow of electrical energy provided by AC source 2 as is used to power AC load 4. AC switch 6 may electrically couple (e.g., connect) AC load 4 to AC source 2 by closing a line connection between links 8 and 10 that spans across two load terminals of AC switch 6. AC switch 6 may electrically de-couple (e.g., disconnect) AC load 4 from AC source 2 by opening the line connection that spans across the two load terminals of AC switch 6. AC switch 6 may be contained in a separate housing, and therefore, electrically isolated from, neutral link 12 which connects AC source 2 to AC load 4. In some examples, AC switch 6 is one or more bi-directional (e.g., “bilateral”) transistor based switches and/or diodes that can block and conduct currents, in two directions.

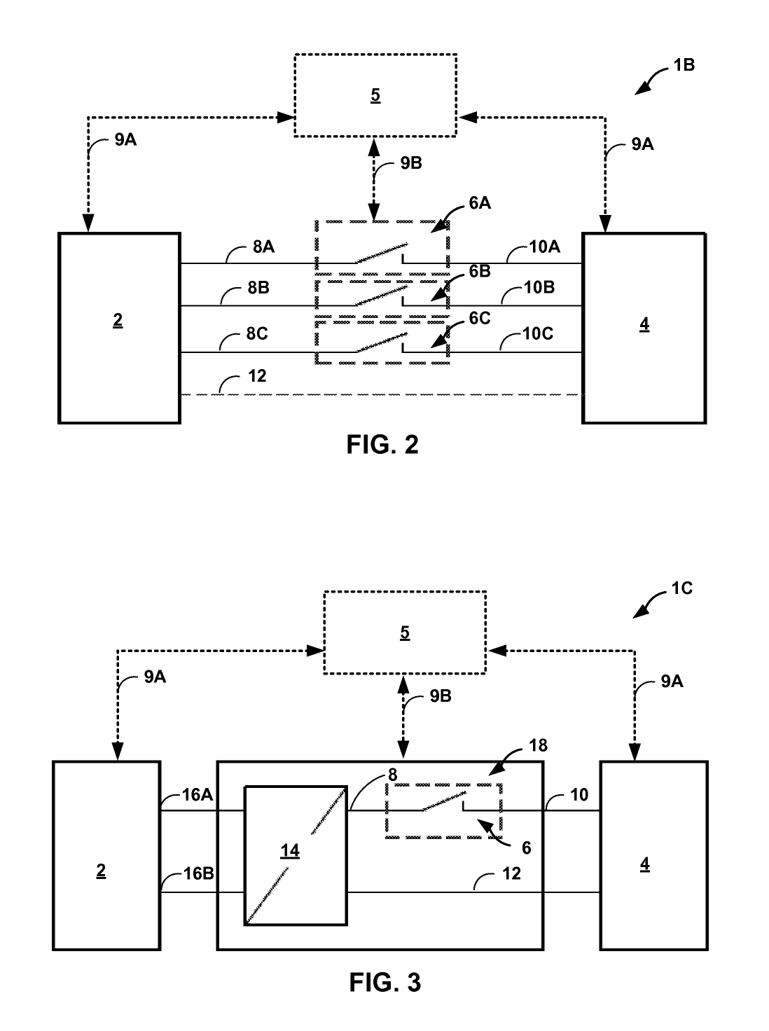

FIG. 2 shows system 1B which controls the flow of three-phase, AC current traveling between AC source 2 and AC load 4. Unlike system 1A which is a single-phase AC power system, three-phase system 1B relies on three AC switches to control the flow of energy between AC source 2 and AC load 4. Each of AC switches 6A-6C represents an example of AC switch 6 from FIG. 1. Each of AC switches 6A-6C controls the flow of a respective phase of the three-phase, AC current traveling between AC source 2 and AC load 4. For example, AC switch 6A may control the flow of the R-phase of the AC current traveling between AC source 2 and AC load 4 across links 8A and 10A. AC switch 6B may control the flow of the S-phase of the AC current traveling between AC source 2 and AC load 4 across links 8B and 10B. And AC switch 6C may control the flow of the T-phase of the AC current traveling between AC source 2 and AC load 4 across links 8C and 10C.

System 1B includes optional, neutral link 12 connecting AC source 2 and AC load 4. In other words, some three-phase applications may include neutral link 12 while other three-phase applications may not. Neutral link 12 is isolated from each of AC switches 6A-6C.

AC source 2 in system 1B represents a three-phase AC power source and AC load 4 represents a three-phase AC load. Examples of AC source 2 include three-phase AC power grids, three-phase AC motors in recuperation mode, and examples of AC load 4 include three-phase AC motors, three-phase AC power grids, etc.

Although not shown specifically in FIGS. 1 and 2, one of ordinary skill in the art will appreciate that in some countries (e.g., countries in North America) AC source 2 and AC load 4 of FIGS. 1 and 2 may be connected “line-to-line” in a two-phase, rather than three-phase or single-phase, AC arrangement. In other words, an example system where AC source 2 and AC load 4 are configured in a two-phase, AC arrangement, AC source 2 and AC load 4 may be separated by two AC switches (e.g., AC switch 6A and 6B) rather than the three AC switches 6A-6C shown in FIG. 2.

Additionally, although not shown specifically in FIG. 2, this disclosure also recognizes that there are some three-phase AC power applications (e.g., a “matrix converter”) that require more than three AC switches than just the three AC switches 6A-6C shown in FIG. 2. For example, in a matrix converter, a three-phase AC source is connected to a three-phase load using nine AC switches 6.

FIG. 3 shows system 1C which controls the flow of AC current traveling between DC source 2 and AC load 4 by relying on power converter 18. Power converter 18 is coupled to DC source 2 via links 16A and 16B. Power converter 18 is coupled to DC load 4 via links 10 and 12. Power converter 18 includes DC/AC converter 14 and AC switch 6 which is coupled to the output of DC/AC converter 14. Power converter 18 relies on AC switch 6 to connect and disconnect the output of DC/AC converter 14 to and from the inputs of AC load 4 by opening or closing the link connection between links 8 and 10.

AC switch 6 may be electrically isolated from link 12. In some examples, DC/AC converter 14 has a single phase output. In other examples, DC/AC converter 14 has a three-phase output in which multiple AC switches may be used to connect and disconnect AC load 4 to and from the outputs of DC/AC converter 14.

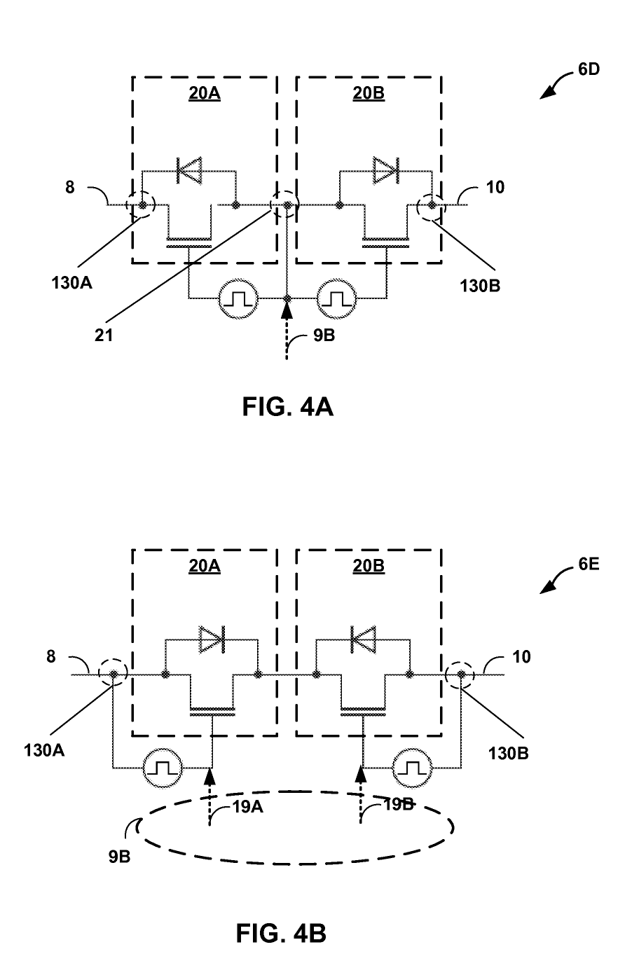

FIGS. 4A and 4B are circuit diagrams illustrating, respectively, AC switches 6D and 6E, as examples of any of switches 6 of systems 1 shown in FIGS. 1-3. For example, each of AC switches 6D and 6E can be used by systems 1 to control the flow of electrical energy between AC source 2 and AC load 4.

AC switches 6D and 6E are examples of bidirectional blocking and conducting switches. That is, each of AC switches 6D and 6E includes two, unidirectional, MOSFET type, devices 20A and 2B arranged back-to-back (otherwise referred to as “anti-serially”) to form a single device that is configured as a bidirectional switch to both block and conduct currents in two directions. Typically, even when switched-off, the intrinsic body diode of each respective MOSFET of unidirectional devices 20A and 2B will always conduct current flowing in one direction. By arranging unidirectional devices 20A and 2B “anti-serially” as is shown in FIGS. 4A and 4B, the combination of two unidirectional devices 20A and 20B can be used to form a single, bidirectional blocking and conducting switch that can be controlled in such a way as to both block and conduct currents flowing two directions.

For example, switches 6D and 6E may each be controlled so as to conduct current flowing from AC load 4 to AC source 2 and may be controlled so as to conduct current flowing from AC source 2 to AC load 4. Switches 6D and 6E may each be controlled so as to block current flowing from AC load 4 to AC source 2 and may be controlled so as to block current flowing from AC source 2 to AC load 4.

FIG. 4A shows unidirectional devices 20A and 20B of AC switch 6D arranged back-to-back or anti-serially sharing a “common source”. In other words, the respective drain electrode of unidirectional devices 20A and 2B are at opposite ends of AC switch 6D and the respective source electrodes are coupled together at a single node in the middle of AC switch 6D. One advantage of a common source arrangement is that the two gate drive electrodes of unidirectional devices 20A and 20B can be connected to common reference point 21. In this way, a common source arrangement may allow both unidirectional devices 20A and 20B to turn on using a single gate driver (e.g., of controller unit 5) that is coupled to AC switch 6D at reference point 21. Said differently, AC switch 6D may be coupled, via link 9B, to a single driver of controller unit 5 that controls the gates of AC switch 6D.

FIG. 4B shows unidirectional devices 20A and 20B of AC switch 6D arranged back-to-back or anti-serially sharing a “common drain”. In other words, the respective source electrode of unidirectional devices 20A and 2B are at opposite ends of AC switch 6E and the respective drain electrodes are shared in the middle of AC switch 6E. In a common drain configuration, two separate gate drivers are required to control unidirectional devices 20A and 20B as the reference potentials of the respective gate electrodes of unidirectional devices 20A and 2B are separated and not shared at a common reference point like is the case with AC switch 6D. AC switch 6E may be coupled, via link 19A of link 9B and 19B of link 9B, to respective drivers of controller unit 5 that control the gates of AC switch 6E.

One disadvantage of both the common source and the common drain anti-serial arrangements shown in FIGS. 4A and 4B is that each arrangement requires two MOSFETs (e.g., unidirectional devices 20A and 20B). Relying on two MOSFETs to perform the function of a single, bidirectional blocking and conducting switch doubles the cost, the size, and R_{DSON} (on-state resistance) of AC switch 6D and 6E as compared to other examples of AC switch 6 that do not rely on an anti-serial arrangement.

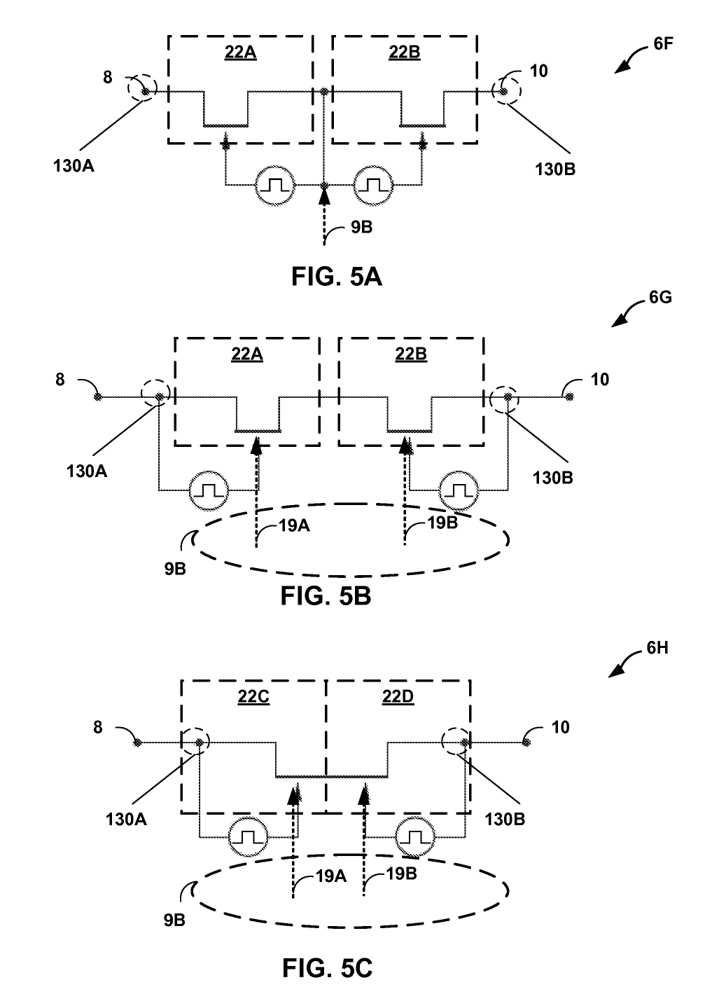

FIGS. 5A-5C are circuit diagrams illustrating example III-V semiconductor based AC switches 6F-6H, as examples of switch(es) 6 of systems 1 shown in FIGS. 1-3. For example, each of AC switches 6F-6H can be used by systems 1 to control the flow of electrical energy between AC source 2 and AC load 4. Similar to AC switches 6D and 6E of FIGS. 4A and 4B, each of AC switches 6F-6H is configured to function as a single, bidirectional blocking and conducting AC switch that both conducts currents and blocks currents from flowing in two, opposite directions.

For example, switches 6F-6H may each be controlled so as to conduct current flowing from AC load 4 to AC source 2 and may be controlled so as to conduct current flowing from AC source 2 to AC load 4. Switches 6F-6H may each be controlled so as to block current flowing from AC load 4 to AC source 2 and may be controlled so as to block current flowing from AC source 2 to AC load 4.

FIGS. 5A and 5B shows AC switches 6F and 6G which each have two III-V semiconductor HEMT devices 22A and 22B. Rather than connecting two unidirectional, MOSFET type, devices, anti-serially like AC switches 6D and 6E, AC switches 6F and 6G rely on an anti-serial arrangement of two III-V semiconductor HEMT devices 22A and 22B to perform bidirectional blocking and conducting of current.

FIG. 5A shows AC switch 6F having an anti-serial arrangement of III-V semiconductor HEMT switch devices 22A and 22B with a common source. AC switch 6F may be coupled, via link 9B, to a single driver of controller unit 5 that control the gates of AC switch 6F.

FIG. 5B shows AC switch 6G having an anti-serial arrangement of III-V semiconductor HEMT switch devices 22A and 22B with a common drain. AC switch 6G may be coupled, via links 19A of link 9B and link 19B of link 9B, to respective drivers of controller unit 5 that control the gates of AC switch 6G.

For each of AC switches 6F and 6G, III-V semiconductor HEMT switch devices 22A and 22B may be formed on separate semiconductor bodies or dies, or alternatively, may be formed (e.g., using monolithic integration techniques) as lateral devices upon a single semiconductor body or die sharing a single, common substrate.

FIG. 5C shows AC switch 6H as being a single III-V semiconductor HEMT device, which is configured to block and conduct currents from two directions. AC switch 6H may be formed as a lateral device upon a single semiconductor body or die sharing a single, common substrate. AC switch 6H is a “true bidirectional switch” arrangement and requires only a single device. In the example of FIG. 5, AC switch 6H is configured as a monolithic integrated bidirectional switch where two transistors share part of the active device area. AC switch 6H comprises two load terminals 130A and 130B and two gate electrodes to control current flow. The two transistors 22C and 22D forming switch 6H share a common drift zone to block voltage and to conduct current in both directions. AC switch 6H may be coupled, via 19A of link 9B and 19B of link 9B, to respective drivers of controller unit 5 that control the double gate of AC switch 6H.

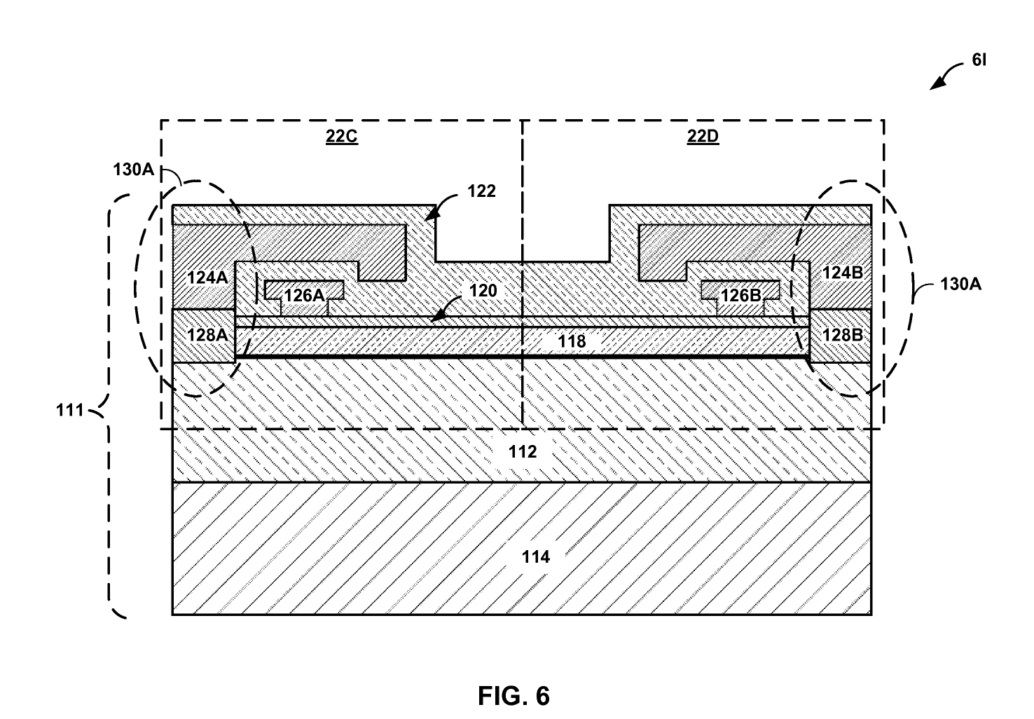

FIG. 6 is a cross sectional layered view of an example AC switch 6I. In the example of FIG. 6, AC switch 6I is a normally-on GaN transistor formed within semiconductor die 111. Semiconductor die 111 includes GaN layer 112, common substrate 114, two-dimensional electron gas (2DEG) region 116, AlGaN layer 118, and GaN cap 120, and passivation layer 122.

Semiconductor die 111 further includes source regions 124A and 124B, gate regions 126A and 126B, and ohmic contacts 128A and 128B of AC switch 6H. Together, ohmic contact 128A and source 124A form a first source terminal 130A of AC switch 6H and ohmic contact 128B and source 124B form the other load terminal 130B of AC switch 6H. Even though FIG. 6 shows a Schottky gate structure it is understood that this device concept may be combined with different types of gate structures such as p-type doped AlGaN gate structures to form a Gate-injection transistor.

As one example, with reference to system 1A of FIG. 1, AC switch 6H may be coupled to a gate driver of controller unit 5 via link 9B and gate terminals 126A and 126B. AC switch 6H may be coupled to AC source 2 and AC load 4, for example, by connecting link 8 to load terminal 130A and connecting link 10 to load terminal 130B.

2DEG region 116 is a current conducting channel of two-dimensional electron gas with the gas of electrons being free to move in two dimensions, but tightly confined in the third dimension. In some examples, 2DEG region 116 may be formed by the hetero junction between two semiconducting materials to confine electrons to a triangular quantum well. In other examples, electrons confined to 2DEG region 116 of HEMTs exhibit higher mobilities than those in MOSFETs, since HEMTs utilize an intentionally un-doped channel thereby mitigating the deleterious effect of ionized impurity scattering.

GaN Cap 120 is optional and represents a layer of GaN layered atop AlGaN layer 118. In some examples, GaN cap 120 may serve to reduce the leakage current of semiconductor die 111 when a Schottky barrier is used as the gate. In other examples, GaN cap 120 may offer an additional barrier to the electrons. Passivation layer 122 is, in some examples, made from Silicon Nitride (SiN). Passivation layer 122 may help decrease current collapse by reducing SiN/GaN/AlGaN interface trap density. Passivation layer 122 has as its primary purpose to passivate the surface of semiconductor die 211 and reduce the influence of surface traps on the device performance. In addition another passivation layer or the same can be also used as gate dielectric to reduce the overall gate leakage current.

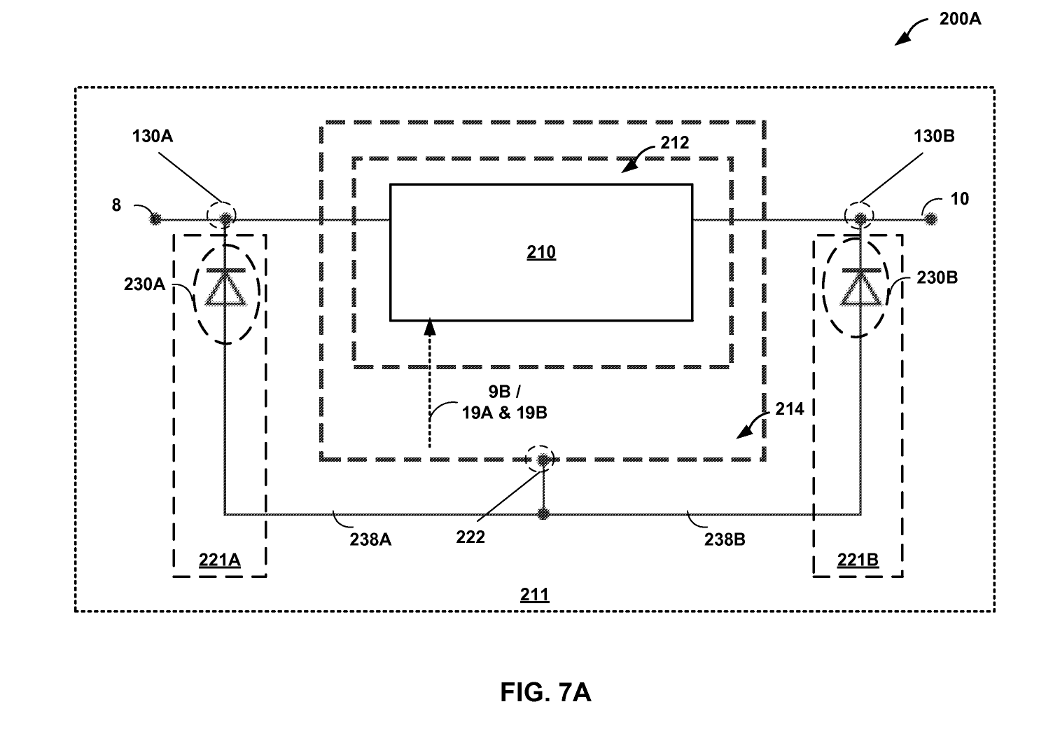

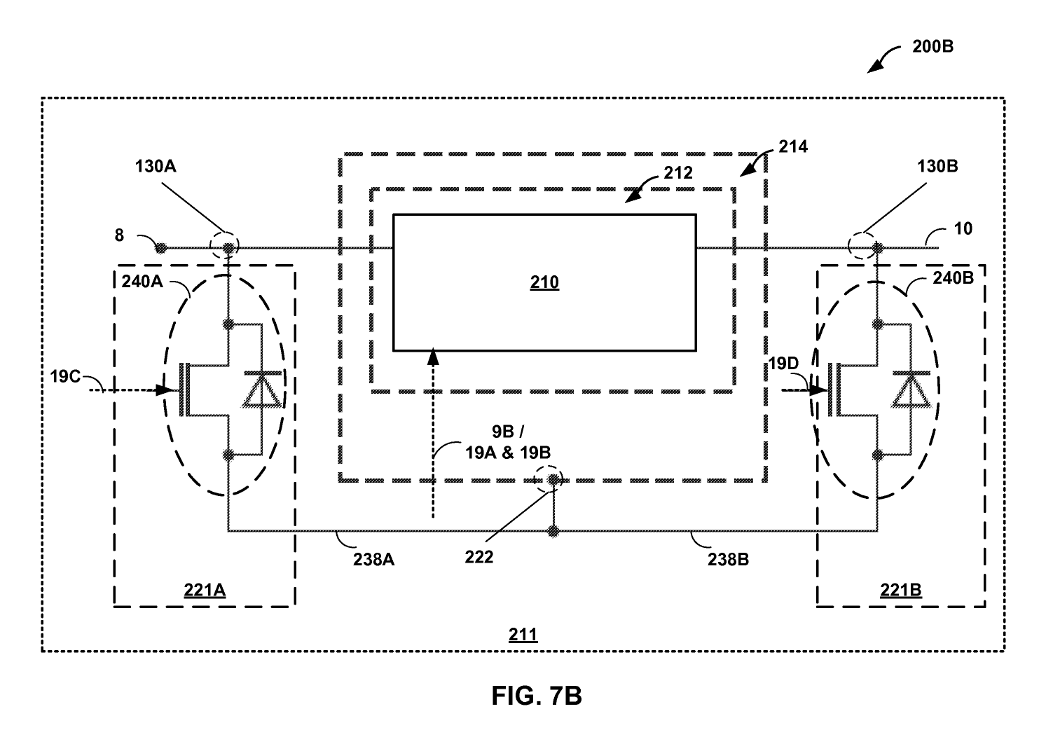

FIGS. 7A and 7B are circuit diagrams illustrating example power circuits 200A and 200B for dynamically configuring AC switch 210, in accordance with one or more aspects of the present disclosure. AC switch 210 includes load terminals 130A and 130B and represents any of the III-V semiconductor based AC switches 6F-6H shown in FIGS. 5A-5C (e.g., a bidirectional blocking and conducting switch). Although described as separate example power circuits, portions of power circuits 200A and 200B may be combined into a single power circuit. For example, coupling circuit 221A of power circuit 200A may be used in combination with coupling circuit 221B of power circuit 200B and together, the two different types of coupling circuits may perform techniques described herein to prevent current collapse in a III-V semiconductor layer.

In each of the examples of FIGS. 7A and 7B, AC switch 210 is formed at least partially within a III-V semiconductor layer 212 which is formed atop a single, common substrate 214 of a single semiconductor die 211. AC switch 210 is a lateral device meaning all the HEMT devices that make up AC switch 210 are monolithically integrated onto one or more III-V semiconductor layers 212 and on the same common substrate 214, of the same semiconductor die 211. Said differently, semiconductor die 211 includes common substrate 214 (e.g., made from Si, SiC, Sapphire, etc.) and III-V semiconductor layer 212 formed atop common substrate 214. In some examples, III-V semiconductor layer 212 is two or more different layers of II-V semiconductor material. That is, the devices of AC switch 210 only need to be formed on the same common substrate 214 but may however be integrated at least partially within different III-V semiconductor layers 212. For example, III-V semiconductor layer 212 may represent two III-V semiconductor layers or “islands,” that do not touch each other, which are formed by the etching away of the area in-between the two III-V semiconductor islands.

AC switch 210 (e.g., a bidirectional switch device) is formed at least partially within III-V semiconductor layer 212 and has at least load terminals 130A and 130B. Although in some examples, AC switch 210 may have more load terminals.

Load terminals 130A and 130B of AC switch 210 correspond to the same load terminals of any of AC switches 6. That is, load terminals 130A of AC switch 210 is coupled to link 8 and load terminal 130B of AC switch 210 is coupled to link 10. The gate(s) of AC switch 210 are coupled to one or more drivers of controller unit 5 via link 9B. In some examples, for instance, when AC switch is a common source type bidirectional switch similar to AC switch 6F, link 9B may be a single link 9B coupling a single driver of controller unit 5 to AC switch 210. In some examples, for instance, when AC switch is a common drain or a single III-V semiconductor HEMT device type bidirectional switch similar to AC switches 6G and 6H, link 9B may include two links (e.g., links 19A and 19B) of link 9B that couple two drivers of controller unit 5 to AC switch 210.

Power circuits 200A and 200B also include, respectively, coupling structures 221A and 221B. Coupling structures 221A and 221B are configured to help to prevent current collapse in AC switch 210. The coupling structures may be arranged external to die 211 or in some examples be arranged at least partially within die 211. Coupling structure structures 221A and 221B may dynamically couple, and re-couple, common substrates 214 of semiconductor die 211 to a lowest potential out of a potential of load terminals 130A and a potential of load terminal 130B. In other words, to avoid any dynamic R_{DSON} effect or any adverse current collapse phenomenon due to III-V semiconductor layer 212, coupling structures 221A and 221B may ensure that common substrate 214 is coupled to, and at the same or at least close to (e.g., minus the voltage drop of the respective coupling structure 221A and 221B) the lowest potential available from the lowest potential at load terminals 130A or 130B of AC switch 210. In this way, coupling structures 221A and 221B may configure common substrate 214 to seemingly always be at or at least near a lowest potential load terminal to repel current mobilities traveling through the conduction channel of AC switch 210, away from the traps of III-V semiconductor layer 212. Coupling structures 221A and 221B may ensure that the potential of substrate 214 does not increase to a potential that is greater than the potential of either of load terminals 130A and 130B. The potential of substrate 214 may however be at or near (e.g., within a few volts above due to a voltage drop across coupling structures 221A and 221B) the lowest potential of the potentials of load terminals 130A and 130. By relying on coupling structures 221A and 221B, power circuits 200A and 200B can be used to dynamically re-configure AC switch 210 to both block and conduct currents in two directions, regardless of whether the voltage across load terminals 130A and 130B is greater than or less than, a voltage threshold (e.g., zero volts). In other words, as the polarity of the AC voltage between AC source 2 and AC load 4 periodically changes, coupling structures 221A and 221B may ensure that the substrate 214 of AC switch 210 always stays close to or at the lower potential of the two potentials applied to load terminals 130A and 130B respectively.

Coupling structure 221A of power circuit 200A of FIG. 7A includes element 230A (e.g., a diode) arranged between common substrate 214 and load terminal 130A. Coupling structure 221B of power circuit 200A includes element 230B arranged between common substrate 214 and load terminal 130B.

Element 230B is configured to electrically couple common substrate 214 to a potential of load terminal 130B in response to a voltage across load terminals 130A and 130B being greater than a threshold (e.g., zero volts) or in response to the potential of load terminal 130B being less than the potential of load terminal 130A. In other words, when the potential at load terminals 130B is less than the potential at load terminal 130A, element 230B of coupling structure 221B is configured to dynamically couple the potential of common substrate 214 to the potential of load terminal 130B so that load terminal 130B and common substrate 214 are approximately at the same potential (e.g., within a few volts but off by an amount that is equal to a voltage drop across coupling structure 221B).

Element 230A is configured to electrically couple common substrate 214 to load terminal 130A in response to a voltage across load terminals 130A and 130B being less than a threshold (e.g., zero volts) or in response to the potential of load terminal 130A being less than the potential of load terminal 130B. In other words, when the potential at load terminals 130A is less than the potential at load terminal 130B, element 230A of coupling structure 221A is configured to dynamically couple common substrate 214 to load terminal 130A so that load terminal 130A and common substrate 214 are at approximately the same potential (e.g., within a few volts but off by a voltage drop across coupling structure 221A).

Elements 230A and 230B are “passive” and not “active” elements. In other words, elements 230A and 230B do not have respective control terminals and therefore are not individually controllable via dedicated control signal inputs. For example, each of elements 230A and 230B may be individual diodes as shown in FIG. 7A. In some examples, each of elements 230A and 230B may be individual Schottky diodes. When power circuit 200A is used in a line frequency application, elements 230A and 230B may only need to switch at a range of fifty to sixty hertz. Elements 230A and 230B may only carry the capacitive displacement current of substrate 214, such capacitive displacement current may be a really low level current (e.g., potentially only a few hundred mA). As diodes, both of elements 230A and 230B may each have a different forward voltage drop. As discussed previously, portions of power circuits 200A and 200B may be combined such that element 230A may be used by coupling structure 221A whereas element 240B may be used with coupling structure 221B. In some examples, each of elements 230A and 230B may be a respective cascode type arrangements of a low voltage diode and a lateral HEMT which together, are configured as the respective diode shown in FIG. 7B. Such cascode type arrangements are described with respect to the additional FIGS.

Coupling structure 221A of power circuit 200B of FIG. 7B includes element 240A (e.g., a transistor based switch) arranged between common substrate 214 and load terminal 130A and coupling structure 221B of power circuit 200B of FIG. 7B includes element 240B arranged between common substrate 214 and load terminal 130B. Elements 240A and 240B are controlled via gate drive signals provided via links 19C and 19D of link 9B by controller unit 5.

For example, controller unit 5, after determining that a voltage across load terminals 130A and 130B is greater than a threshold (e.g., zero volts) or after determining that the potential at load terminal 130B is less than the potential at load terminal 130A, may generate a gate drive signal across link 19D to activate element 240B and cause element 240B to electrically, and dynamically couple common substrate 214 to load terminal 130B. In other words, when controller unit 5 determines that the potential at load terminals 130B is less than the potential at load terminal 130A, controller unit 5 may configure element 240B of coupling structure 221B to dynamically couple common substrate 214 to load terminal 130B so that load terminal 130B and common substrate 214 are at approximately the same potential (e.g., within a few volts but off by a voltage drop across the respective coupling structure 221A or 221B).

Controller unit 5, after determining that a voltage across load terminals 130A and 130B is less than the threshold (e.g., zero volts) or after determining that the potential at load terminal 130A is less than the potential at load terminal 130B, may generate a gate drive signal across link 19C to activate element 240A and configure element 240A to electrically, and dynamically couple common substrate 214 to load terminal 130A. In other words, when controller unit 5 determines that the potential at load terminal 130A is less than the potential at load terminal 130B, controller unit 5 may configure element 240A of coupling structure 221B to dynamically couple common substrate 214 to load terminal 130A so that load terminal 130A and common substrate 214 are at approximately the same potential (e.g., within a few volts but off by a voltage drop across the respective coupling structure 221A or 221B).

Elements 240A and 240B are “active” and not “passive” elements. In other words, elements 240A and 240B do have respective control terminals (e.g., see links 19C and 19D) and therefore are individually controllable via dedicated control signal inputs (e.g., provided by control unit 5 via links 19C and 19D). For example, each of elements 240A and 240B may be individual transistor based switch devices as shown in FIG. 7B. Active elements 240A and 240B may have antiparallel body diodes as shown in FIG. 7B. The switches may be activated based on control signals received via link 9 and controller unit 5. For example, controller unit 5 may determine whether the voltage across load terminals 130A and 130B is greater than or less than the voltage threshold. Based on a detection of polarity of the voltage across load terminals 130A and 130B, controller unit 5 may generate control signals across links 19C and 19D of link 9B that cause elements 240A and 240B to switch-on or switch-off.

In some examples, coupling structures 221A and 221B may be monolithically integrated onto die 211 and formed at least partially within III-V semiconductor layer 212 on die 211. In some examples, coupling structures 221A and 221B may be at least partially integrated about and external to die 211.

In some examples, controller unit 5 may be configured to control coupling structures 221B to dynamically couple common substrate 214 of semiconductor die 211 to the lowest potential out of the potential of load terminal 130A and the potential of load terminal 130B of AC switch 210. For instance, as one example, controller unit 5 may receive information (e.g., via links 9A and/or 9C from AC source 2 and/or AC load 4) about the voltage between AC source 2 and AC load 4. For example, controller unit 5 may measure the voltage across load terminals 130A and 130B. Whenever the voltage changes polarity (e.g., goes from a positive to a negative value or a negative to a positive value), controller unit 5 may determine that its time to alternate which coupling structure 221A and 221B is active. In some examples, controller unit 5 may receive information directly from AC switch 210 and link 9B indicating the voltage across load terminals 130A and 130B. In any event, based on that information about the voltage across AC switch 210, controller unit 5 may determine whether the potential at load terminal 130A or the potential at load terminal 130B is the lowest potential of AC switch 210.

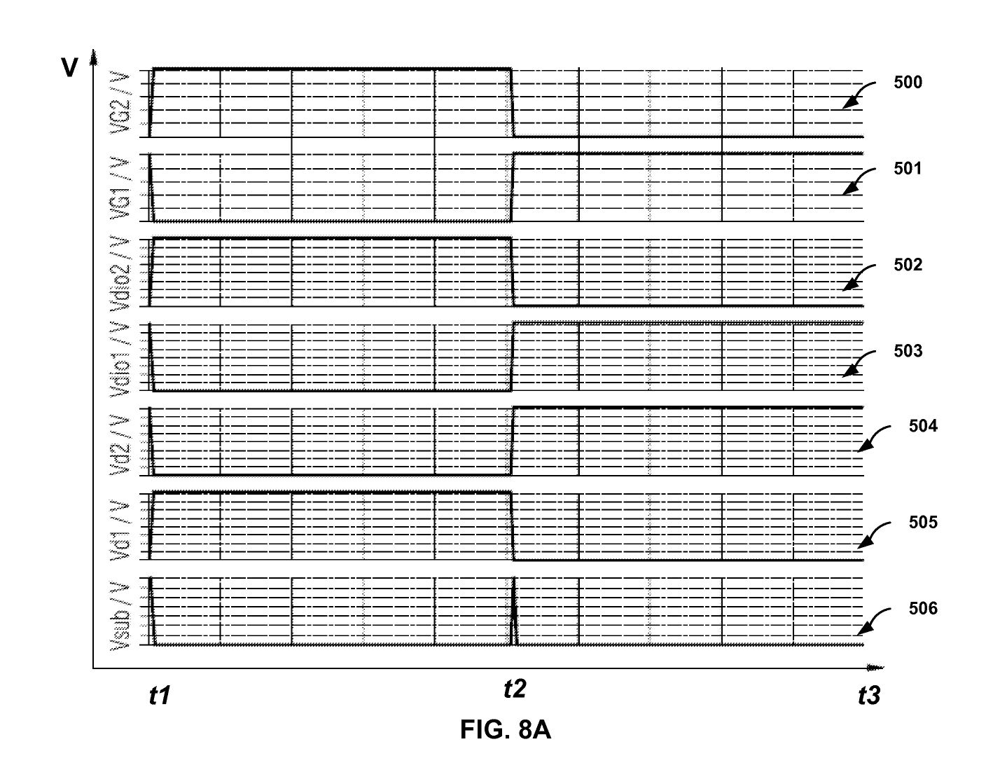

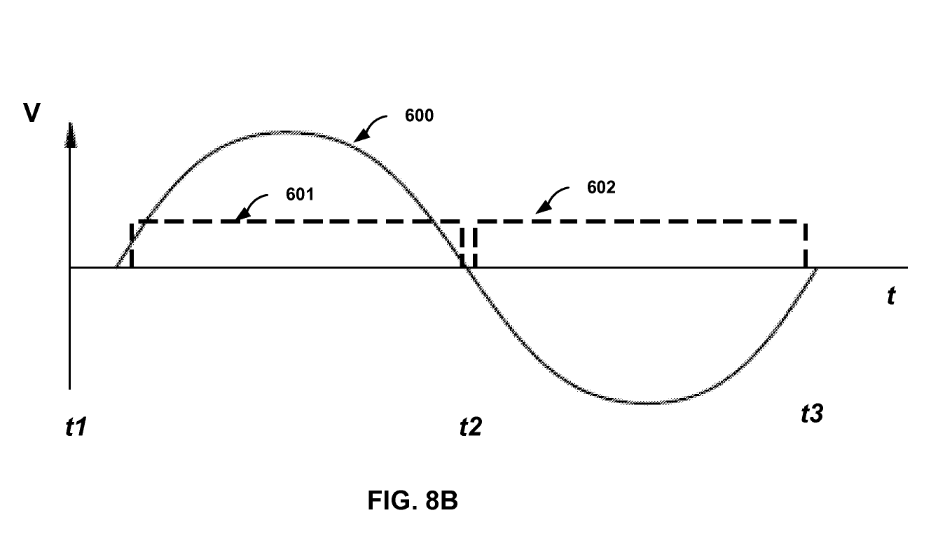

FIG. 8A is a timing diagram illustrating voltage characteristics of power circuit 200A shown in FIG. 7A. For example, FIG. 8A includes voltage plots 500-506 that each illustrate a voltage level at a portion of power circuit 200A between times t1 and t3 during operation of AC switch 210. Plots 500 and 501 show the gate drive signals across links 19A and 19B for controlling AC switch 210. Plot 502 shows the voltage across element 230B between times t1 and t3 being at opposite polarity of the voltage across element 230A between times t1 and t3 shown by plot 503. Plot 504 shows the voltage at load terminal 130B between times t1 and t3 being at opposite polarity of the voltage at load terminal between times t1 and t3 shown by plot 505. As shown by plot 506, because of coupling structures that dynamically couple common substrate 214 to a lowest load terminal potential, the potential of common substrate 214 follows the lower potential of either load terminal 130A or load terminal 130B of plots 504 and 505.

FIG. 8B is a timing diagram illustrating voltage characteristics of power circuit 200B shown in FIG. 7B. For example, FIG. 8B includes voltage plots 600-603 that each illustrate a voltage level at a portion of power circuit 200B between times t1 and t3 during operation of AC switch 210. Plot 600 shows the voltage between load terminals 130A and 130B between times t1 and t3. Plot 601 shows the gate drive signal according to the techniques of this disclosure at the gate terminal of element 240B between times t1 and t3 and plot 602 illustrates the gate drive signal at the gate terminal of element 240A between the same times. In other words, FIG. 8A shows an implementation of power circuit 200B, where because of coupling structures that dynamically couple common substrate 214 to a lowest load terminal potential, element 240B is operating in an on-state at a positive voltage between load terminals 130A and 130B, and where element 240A is operating in an on-state at a negative voltage between load terminals 130A and 130B.

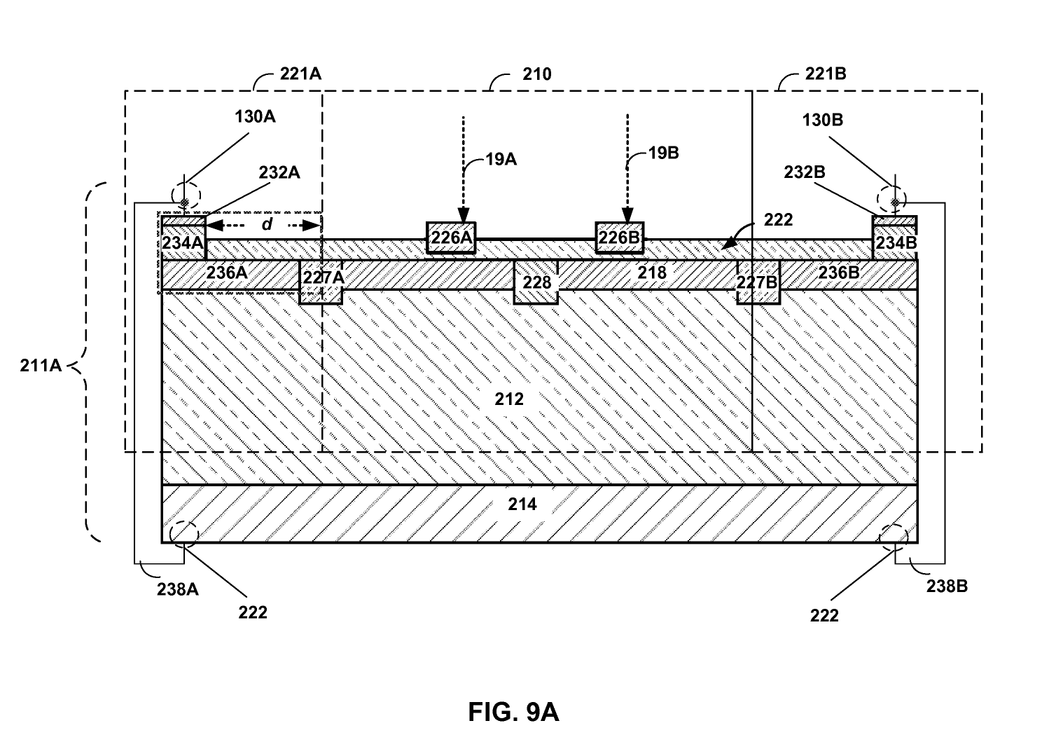

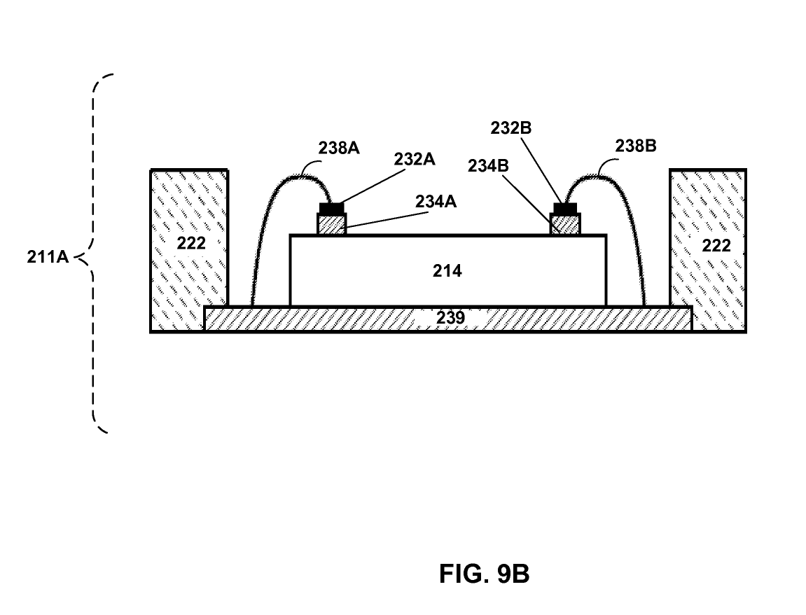

FIG. 9A is a cross sectional layered view of semiconductor die 211A that includes an example coupling structure 221A of FIG. 7A laterally integrated with AC switch 210 (e.g., bidirectional GaN based switch) that shares the same structure as AC switch 6F shown of FIG. 5A. Semiconductor die 211A includes elements 230A and 230B laterally integrated on opposite sides of AC switch 210. In the example of FIG. 9A, elements 230A and 230B are pn-diodes and AC switch 210 is a common source bidirectional GaN based switch. For ease of description, the following figures are described primarily with respect to GaN based switches and GaN layers, other III-V semiconductor based switches and layers can be used. For example, AC switch 210 may be a III-V semiconductor type switch that has any one of a BN layer, BP layer, Bas layer, AN layer, AlP layer, AlAs layer, AlSb layer, GaN layer, GaP layer, GaAs layer, GaSb layer, InN layer, InP layer, InAs layer, InSb layer, TiN layer, TiP layer, TiAs layer, TiSb layer, or any other III-V type layer made from a III-V semiconductor material.

AC switch 210 has load terminals 130A and 130B which also correspond, respectively, to drain terminals 227A and 227B. AC switch 210 is a common source type bidirectional switch with source terminal 228. AC switch 210 further includes gate terminals 226A and 226B. Controller unit 5 may provide gate control signals via links 19A and 19B of link 9B to switch AC switch 210 on and off to control whether current flows between load terminals 130A and 130B within a 2DEG region (not shown) of die 211A that is adjacent to AlGaN layer 218 and GaN layer 212.

Element 230A includes metal contact 232A atop p-type doped AlGaN layer 234A. The blocking pn-junction of element 230A is formed at the interface of p-type doped AlGaN layer 234A and n-type doped AlGaN layer 218. The cathode of element 230A corresponds to drain terminal 227A of AC switch 210 and is likewise, coupled to link 8 at load terminal 130A. Driftzone 236A of element 230A is formed within AlGaN layer 218. A certain distance between p-type doped AlGaN layer 234A and load terminal 130A may be required. For example, for a six hundred volt application, p-type doped AlGaN layer 234A and load terminal 130A may be separated by a range in distance of approximately 8 um to 15 um. Metal contact 232A of element 230A is coupled to common substrate 214 at node 222 by means of bond wire 238A.

Element 230B includes metal contact 232B atop p-type doped AlGaN layer 234B. The blocking pn-junction of element 230B is formed at the interface of p-type doped AlGaN layer 234B and n-type doped AlGaN layer 218. The cathode of element 230B corresponds to drain terminal 227B of AC switch 210 and is likewise, coupled to link 10 at load terminal 130B. Driftzone 236B of element 230B is formed within AlGaN layer 218. Element 230B requires a similar distance between p-type doped AlGaN layer 234B and load terminal 130B as is required for element 230A. Metal contact 232B of element 230B is coupled to common substrate 214 at node 222 by means of bond wire 238B.

As such, FIG. 9A shows AC switch 210 (e.g., a bidirectional switch) formed at least partially within GaN layer 212 and monolithically integrated on semiconductor die 211A, with coupling structure 221A (e.g., including elements 230A and 230B and bond wires 238A and 238B). Coupling structure 221A of semiconductor die 2111A is configured to prevent current collapse in GaN layer 212 by dynamically coupling (e.g., while AC source 2 and AC load 4 exchange energy) common substrate 214 to a lowest potential load terminal from load terminal 130A and load terminal 130B.

FIG. 9B is a conceptual diagram illustrating an example bonding option for semiconductor die 211A of FIG. 9A. FIG. 9B shows semiconductor die 211A mounted with a conducting adhesive technology (e.g., soldering, metal filled glue, etc.) to metalized island 239. metal contacts 232A and 232B atop p-type doped AlGaN layers 234A and 234B connected by bond wires 238A and 238B to metalized island 239. Metalized island 239 is electrically connected to common substrate 214.

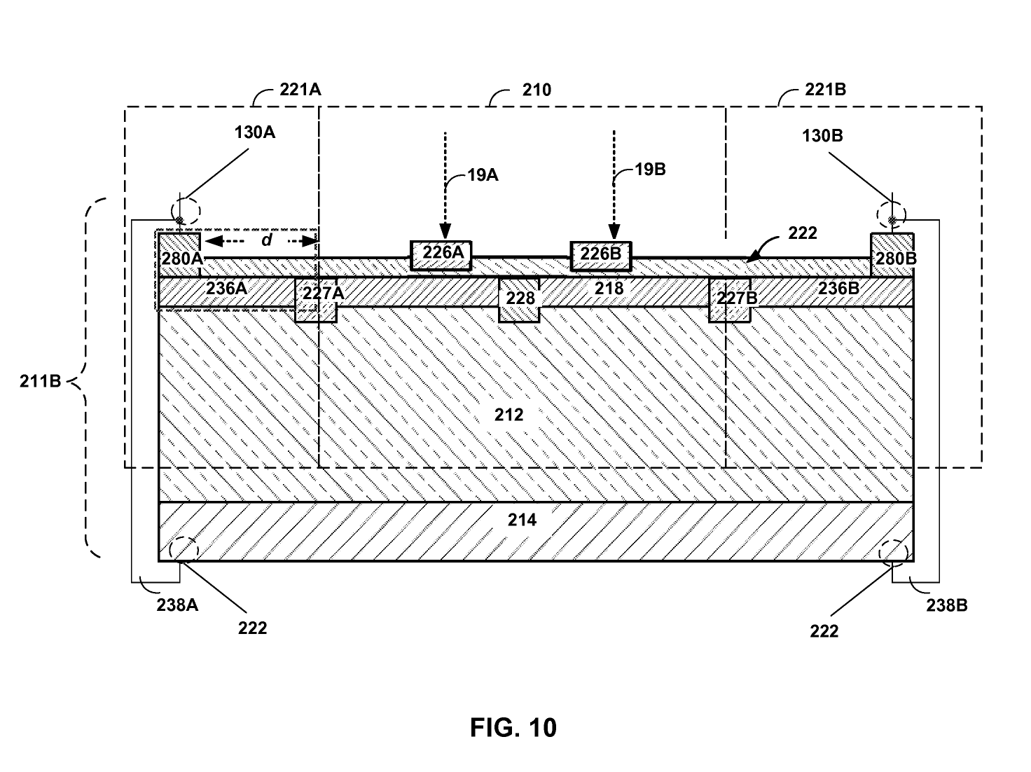

FIG. 10 is a cross sectional layered view of semiconductor die 211B that includes an additional example of coupling structure 221A of FIG. 7A laterally integrated with AC switch 210 (e.g., bidirectional GaN based switch) that shares the same structure as AC switch 6F shown of FIG. 5A. Semiconductor die 211B includes elements 230A and 230B laterally integrated on opposite sides of AC switch 210. In the example of FIG. 10, elements 230A and 230B are Schottky diodes and AC switch 210 is a common source bidirectional GaN based switch.

Semiconductor die 211B shares similarities with semiconductor die 211A of FIG. 9A. However, element 230A of FIG. 10 includes Schottky contact 280A instead of metal contact 232A and p-type doped AlGaN layer 234A of element 230A of FIG. 9A. Schottky contact 280A shares an interface with drift zone 236A. Schottky contact 280A is coupled to common substrate 214 at node 222 by means of bond wire 238A. To prevent current collapse while outputting current to AC load 4, element 230A is configured to electrically couple common substrate 214 to load terminal 130A of AC switch 210 in response to a voltage across load terminal 130A and load terminal 130B of AC switch 210 being less than a threshold (e.g., zero volts) or the potential at load terminal 130A being less than the potential at load terminal 130B.

Element 230B of FIG. 10 includes Schottky contact 280B instead of metal contact 232B and p-type doped AlGaN layer 234B of element 230B of FIG. 9A. Schottky contact 280B shares an interface with drift zone 236B. Schottky contact 280B is coupled to common substrate 214 at node 222 by means of bond wire 238B. To prevent current collapse while outputting current to AC load 4, element 230B is configured to electrically couple common substrate 214 to load terminal 130B of AC switch 210 in response to a voltage across load terminal 130A and load terminal 130B of AC switch 210 being greater than a threshold (e.g., zero volts) or the potential at load terminal 130B being less than the potential at load terminal 130A. In some examples, die 211B may also include an additional III-V semiconductor material type cap layer on top of p-type doped AlGaN layer 234B to reduce the leakage current of element 230B as element 230B is configured as a Schottky diode.

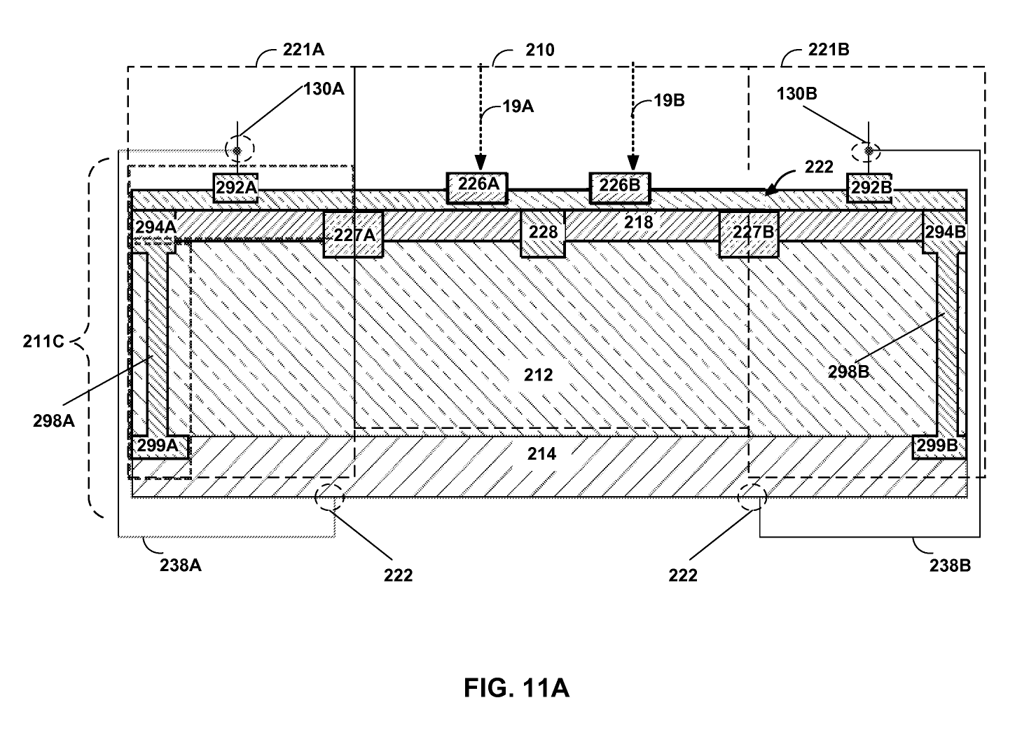

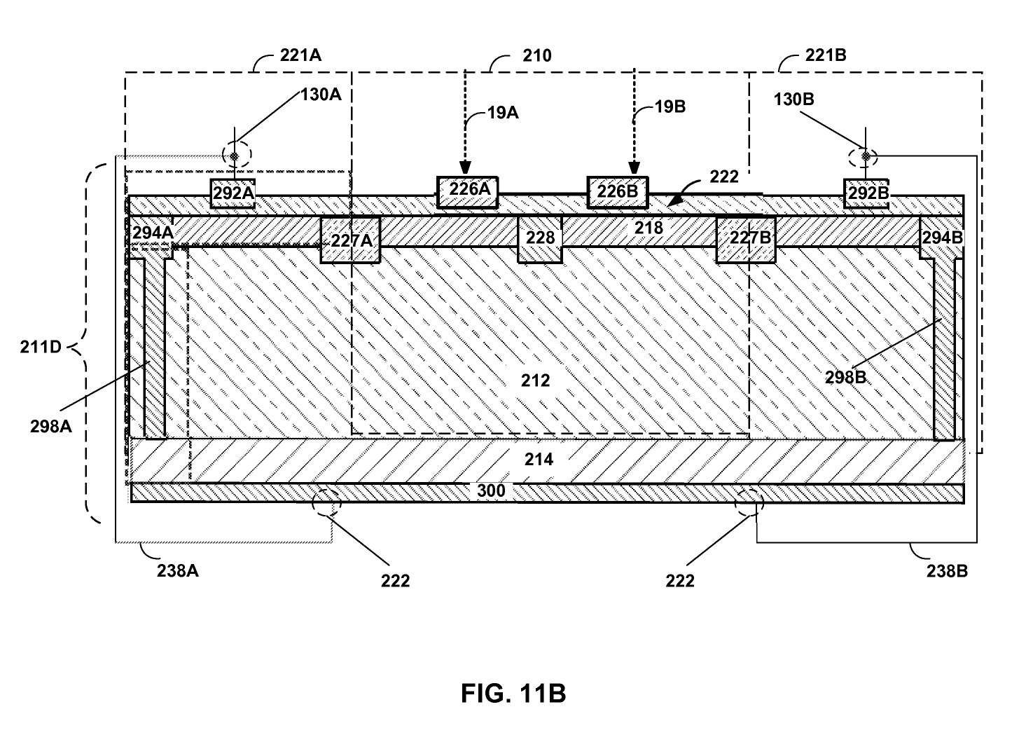

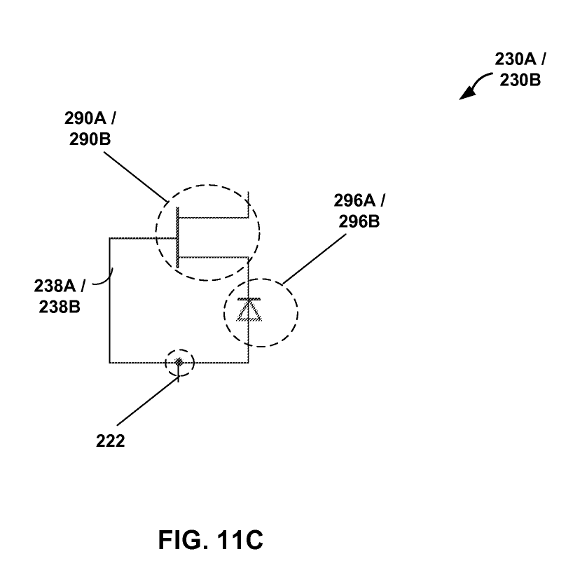

FIGS. 11A and 11B are cross sectional layered views of example semiconductor dies 211C and 211D that each include additional examples of coupling structure 221A of FIG. 7A laterally integrated with AC switch 210 (e.g., bidirectional GaN based switch) that shares the same structure as AC switch 6F shown of FIG. 5A. Semiconductor dies 211C and 211D each include elements 230A and 230B laterally integrated on opposite sides of AC switch 210. AC switch 210 is a common source bi directional GaN based switch. In the example of FIGS. 11A and 11B, elements 230A and 230B are respective cascode type arrangements of devices (e.g., a low voltage diode and a lateral HEMT) that are configured as a pn-diode. Refer to FIG. 11C for a circuit diagram of each of elements 230A and 230B.

Element 230A of semiconductor die 211C includes low-voltage diode 296A and high-voltage lateral GaN device 290A. High-voltage lateral GaN device 290A must be a normally-on GaN device in order to make die 211C operational. For instance, the cascode type arrangement of low voltage diode 296A, 296B and lateral HEMT 290A, 290B are connected in a so-called cascode configuration, that is low voltage diode 296A, 296B pushes the voltage of the source of lateral HEMT 290A, 290B up and down in voltage whereas the gate electrode of lateral HEMT 290A, 290B always stays on a lowest potential.

GaN device 290A has source contact 294A, gate electrode 292A and drain contact 293A. Drain contact 293A corresponds to load terminal 130A of AC switch 210. Gate electrode 292A is connected to common substrate 214 by means of bond wire 238A. Source contact 294A is connected via metal plug 298A to n+ area 299A at the interface between GaN layer 212 and common substrate 214. In some examples, metal plug 298A may be a highly doped n-type poly. Low voltage diode 296A is formed at the interface of n+-area 299A with the common substrate 214. Element 230B of FIG. 11A includes similar features as element 230A. In the example of FIG. 11A, common substrate is p-doped.

Elements 230A and 230B of semiconductor die 211D are nearly identical to elements 230A and 230B of semiconductor die 211C. However, common substrate 214 of semiconductor die 211D is n-type doped and includes p-type doped layer 300 below common substrate 214. Gate electrode 292A is connected to p-type doped layer 300 at node 222 by means of bond wire 238A. In addition, diode 296A of semiconductor die 211D is formed at the interface between n-type substrate 214 and p-type doped layer 300.

FIG. 11C is a circuit diagram illustrating an example of elements 230A and 230B of the additional examples of the coupling structure 221A of FIGS. 11A and 11B. FIG. 11C shows bond wire 238A, 238B connecting gate electrode 292A, 292B of GaN device 290A, 290B to node 222. The cathode of low voltage diode 296A, 296B is coupled to source contact 294A, 294B of GaN device 290A, 290B.

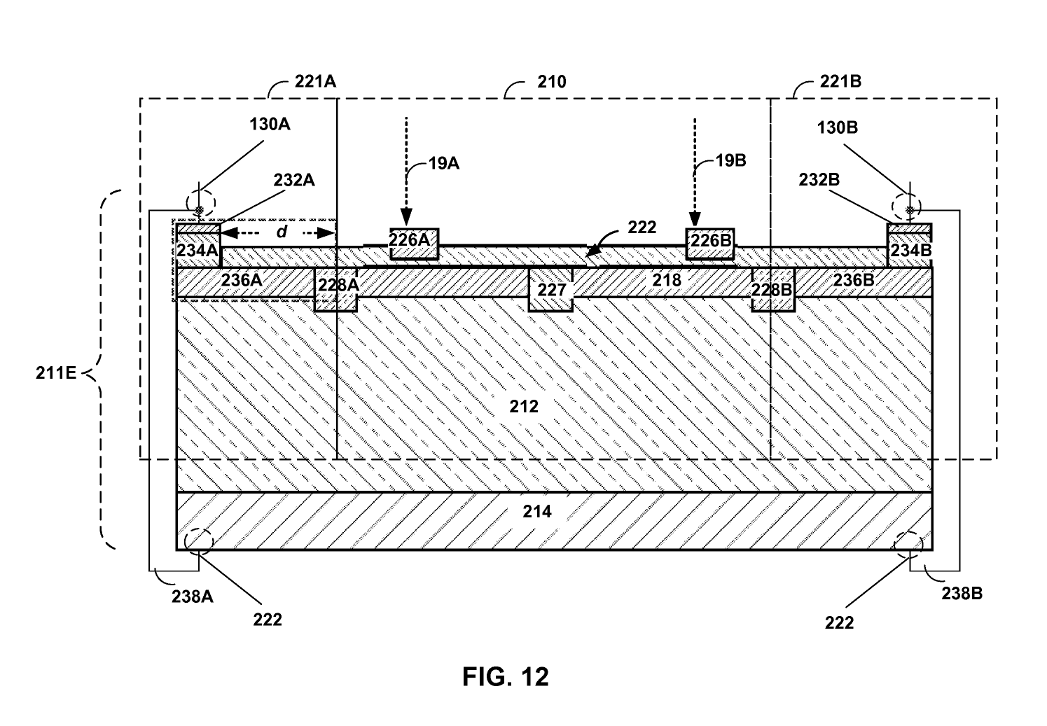

FIG. 12 is a cross sectional layered view of semiconductor die 211E that includes an example of coupling structure 221A of FIG. 7A laterally integrated with AC switch 210 (e.g., bidirectional GaN based switch) that shares the same structure as AC switch 6G of FIG. 5B. In the example of FIG. 12, elements 230A and 230B are pn-diodes. Semiconductor 211E is similar to semiconductor 211A of FIG. 9A however AC switch 210 of semiconductor 211E is a common drain type bidirectional switch.

Load terminals 130A and 130B of AC switch 210 of semiconductor 211E correspond to source terminals 228A and 228B. The cathode of element 230A corresponds to source terminal 228A of AC switch 210 and is likewise, coupled to link 8 at load terminal 130A. The cathode of element 230B corresponds to source terminal 228B of AC switch 210 and is likewise, coupled to link 10 at load terminal 130B.

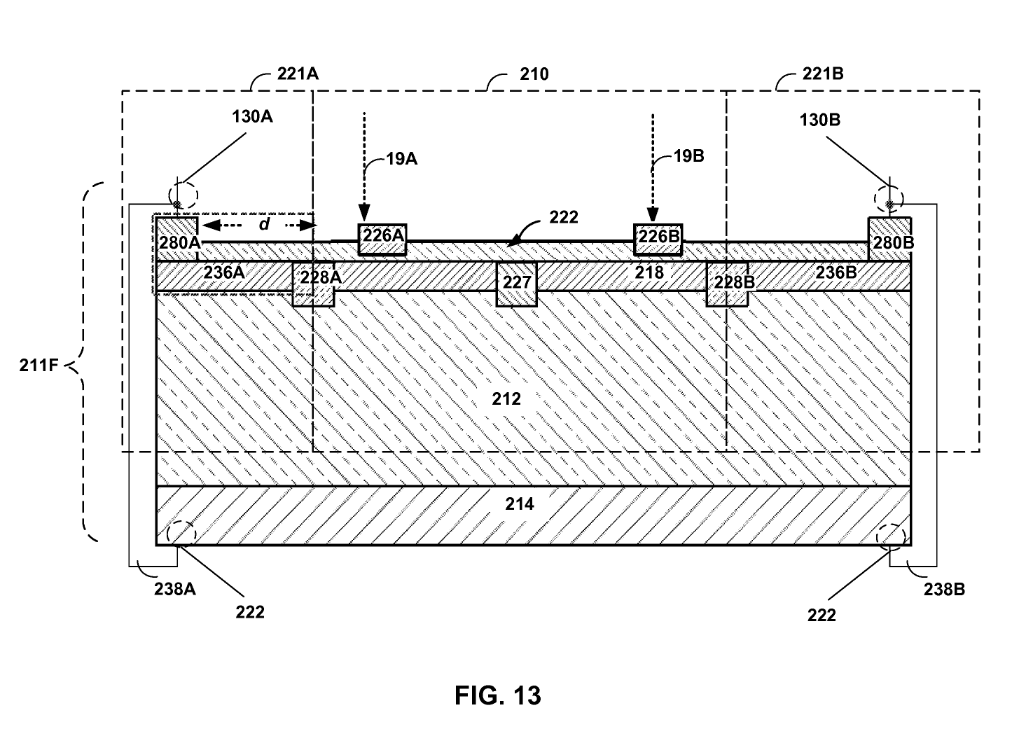

FIG. 13 is a cross sectional layered view of semiconductor die 211F that includes an example of coupling structure 221A of FIG. 7A laterally integrated with AC switch 210 (e.g., bidirectional GaN based switch) that shares the same structure as AC switch 6G of FIG. 5B. In the example of FIG. 13, elements 230A and 230B are Schottky diodes. Semiconductor 211F is similar to semiconductor 211B of FIG. 10 however AC switch 210 of semiconductor 211F is a common drain type bidirectional switch.

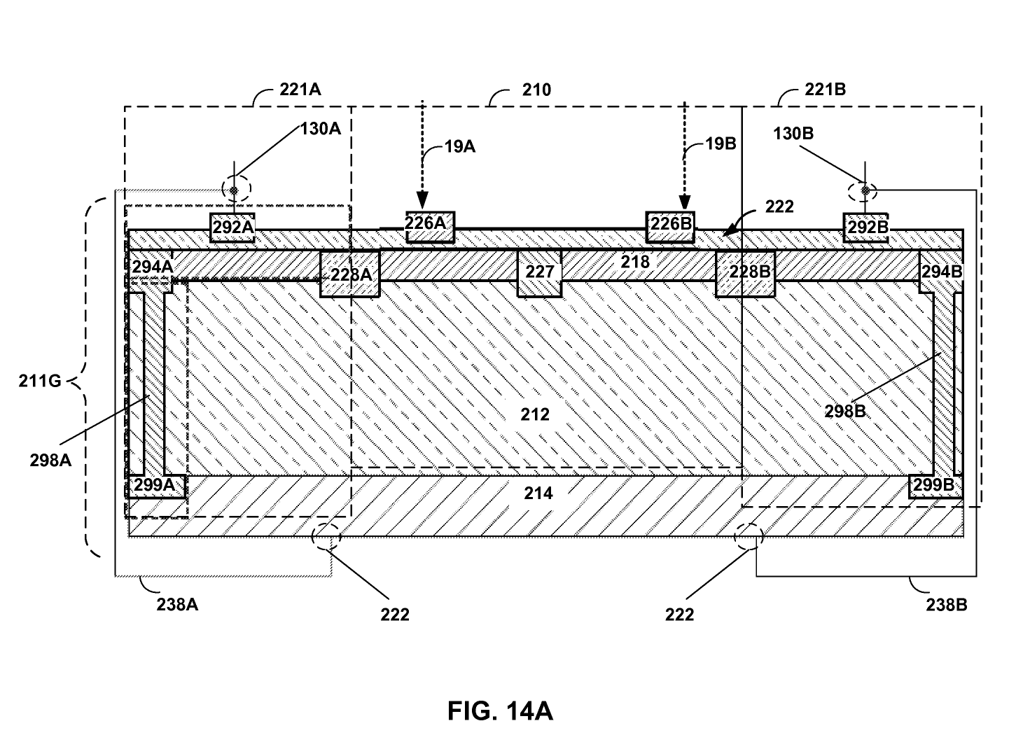

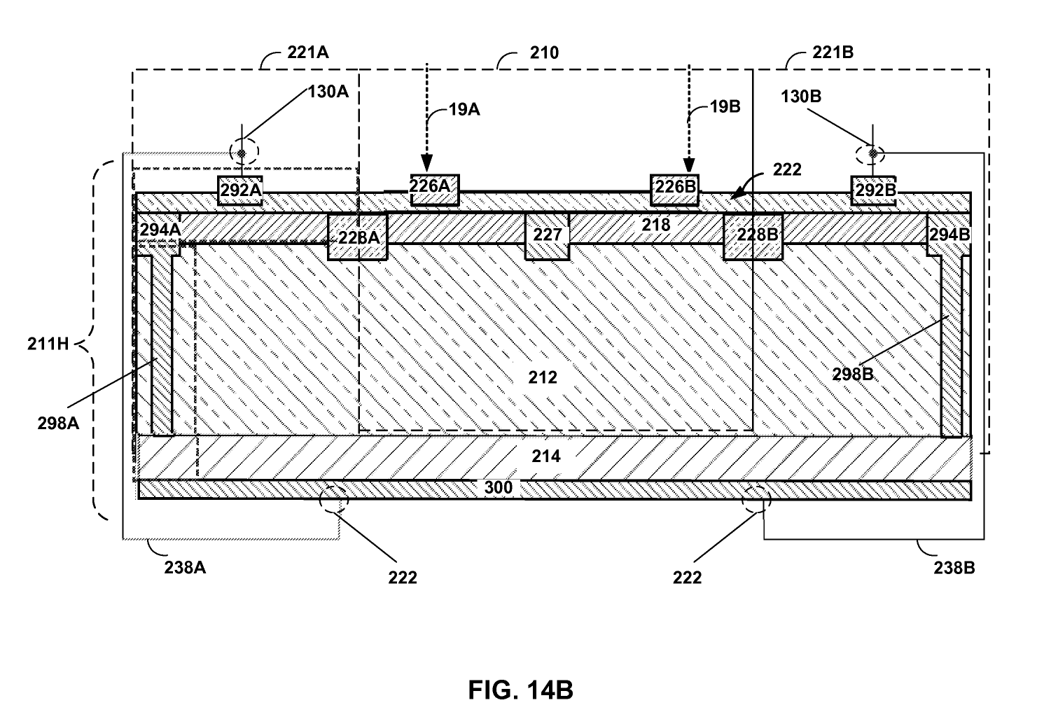

FIGS. 14A and 14B are cross sectional layered views of semiconductor dies 211G and 211H that each include an additional example of coupling structure 221A of FIG. 7A laterally integrated with AC switch 210 (e.g., bidirectional GaN based switch) that shares the same structure as AC switch 6G of FIG. 5B. In the example of FIGS. 14A and 14B, elements 230A and 230B are respective cascode type arrangements of devices (e.g., a low voltage diode and a lateral HEMT) that are configured as a pn-diode, for instance, as shown in FIG. 11C. Semiconductor 211G is similar to semiconductor 211C of FIG. 11A however AC switch 210 of semiconductor 211G is a common drain type bidirectional switch. Semiconductor 211H is similar to semiconductor 211D of FIG. 11B however AC switch 210 of semiconductor 211H is a common drain type bidirectional switch. Source terminal 228A of AC switch 210 is the cathode of element 230A and source terminal 228B is the cathode of element 230B.

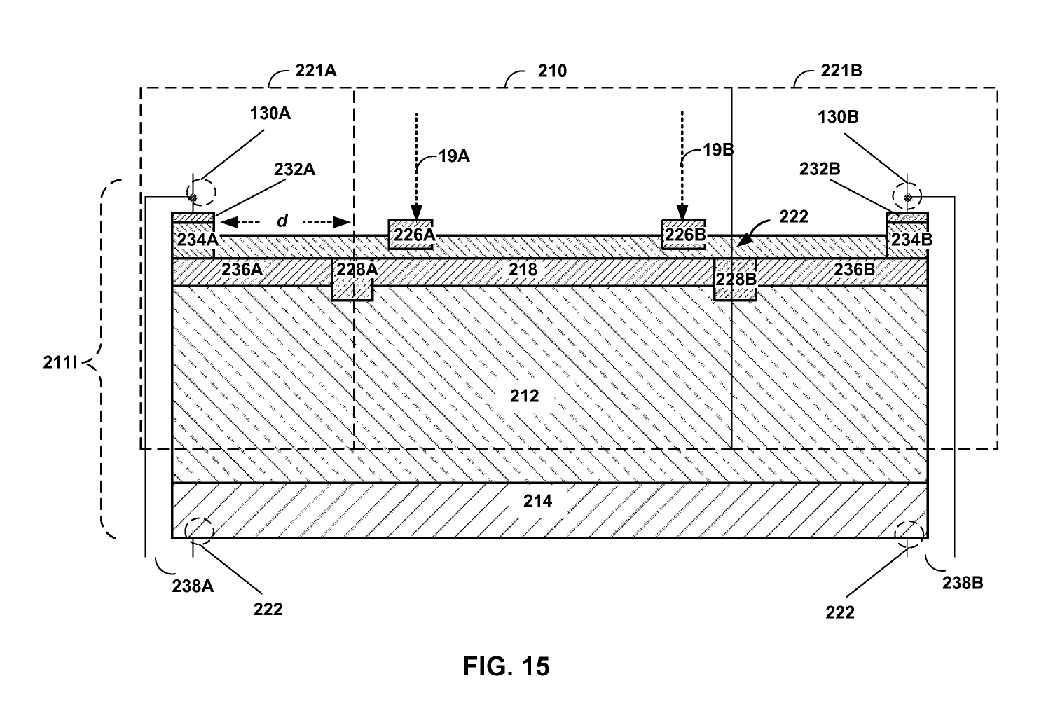

FIG. 15 is a cross sectional layered view of semiconductor die 211I that includes an example of coupling structure 221A of FIG. 7A laterally integrated with AC switch 210 (e.g., bidirectional GaN based switch) that shares the same structure as AC switch 6H of FIG. 5C. In the example of FIG. 15, elements 230A and 230B are pn-diodes. Semiconductor 211I is similar to semiconductor 211A of FIG. 9A and semiconductor 211E of FIG. 12 however AC switch 210 of semiconductor 211I is a true, bidirectional switch that has only a single GaN based device. Source terminal 228A of AC switch 210 is also the cathode of element 230A and source terminal 228B is the cathode of element 230B.

Load terminals 130A and 130B of AC switch 210 of semiconductor 211E correspond to source terminals 228A and 228B. The cathode of element 230A corresponds to source terminal 228A of AC switch 210 and is likewise, coupled to link 8 at load terminal 130A. The cathode of element 230B corresponds to source terminal 228B of AC switch 210 and is likewise, coupled to link 10 at load terminal 130B like that shown in FIG. 5C.

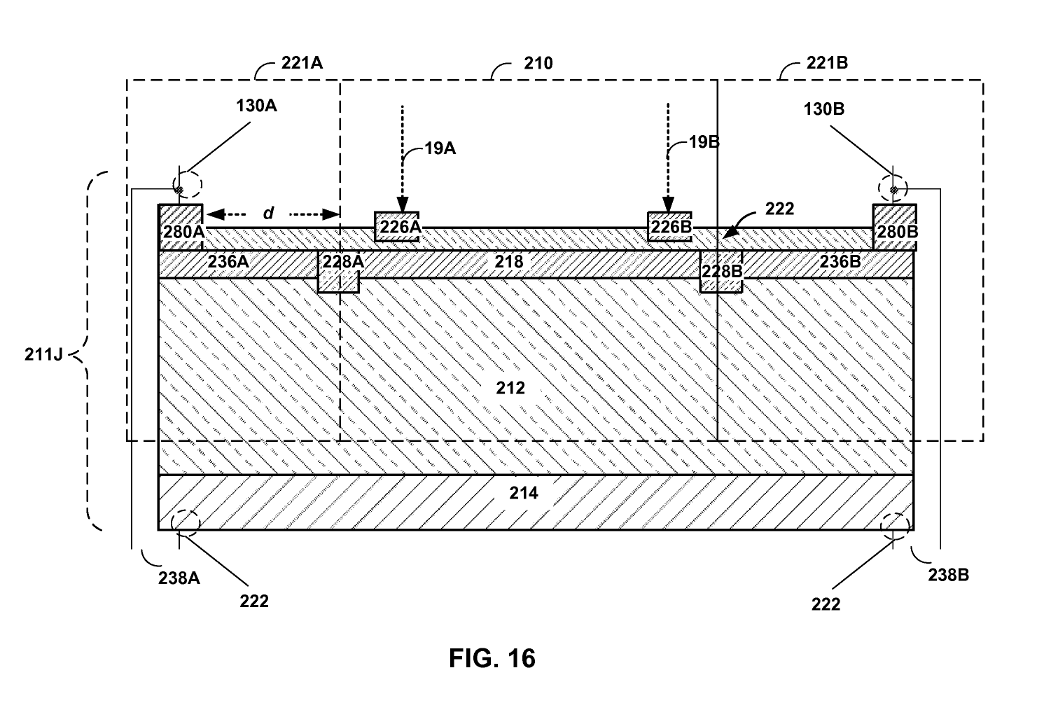

FIG. 16 is a cross sectional layered view of semiconductor die 211J that includes an additional example of coupling structure 221A of FIG. 7A laterally integrated with AC switch 210 (e.g., bidirectional GaN based switch) that shares the same structure as AC switch 6H of FIG. 5C. In the example of FIG. 16, elements 230A and 230B are Schottky diodes. Semiconductor 211J is similar to semiconductor 211B of FIG. 10 and semiconductor 211F of FIG. 13, however AC switch 210 of semiconductor 211J is a true, bidirectional switch that has only a single GaN based device like that shown in FIG. 5C. Source terminal 228A of AC switch 210 is also the cathode of element 230A and source terminal 228B is the cathode of element 230B.

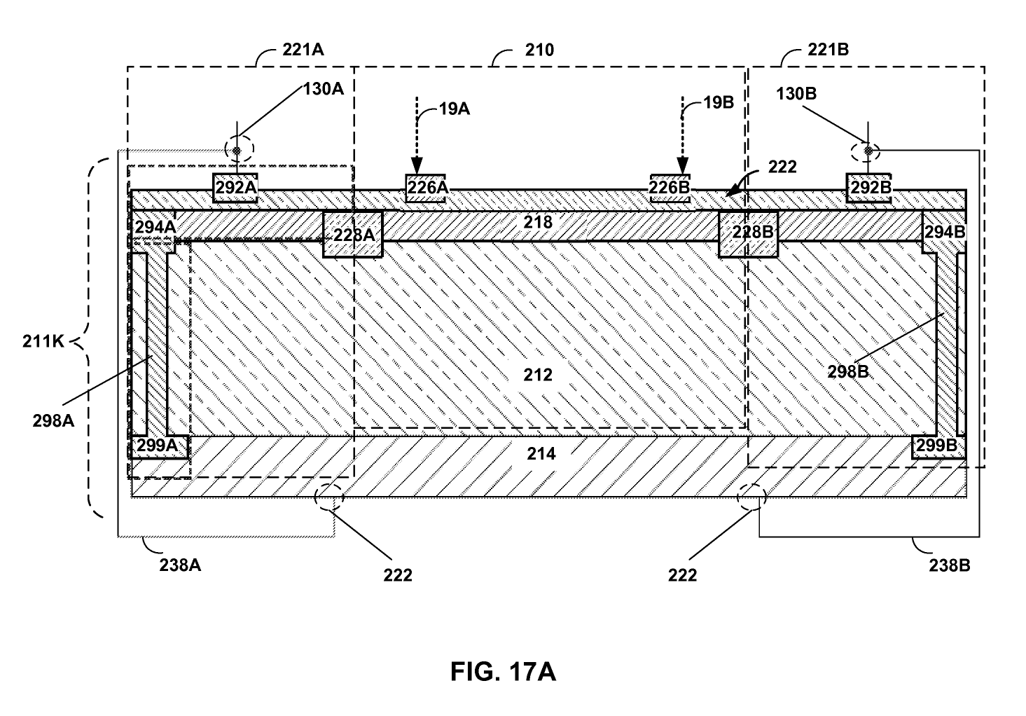

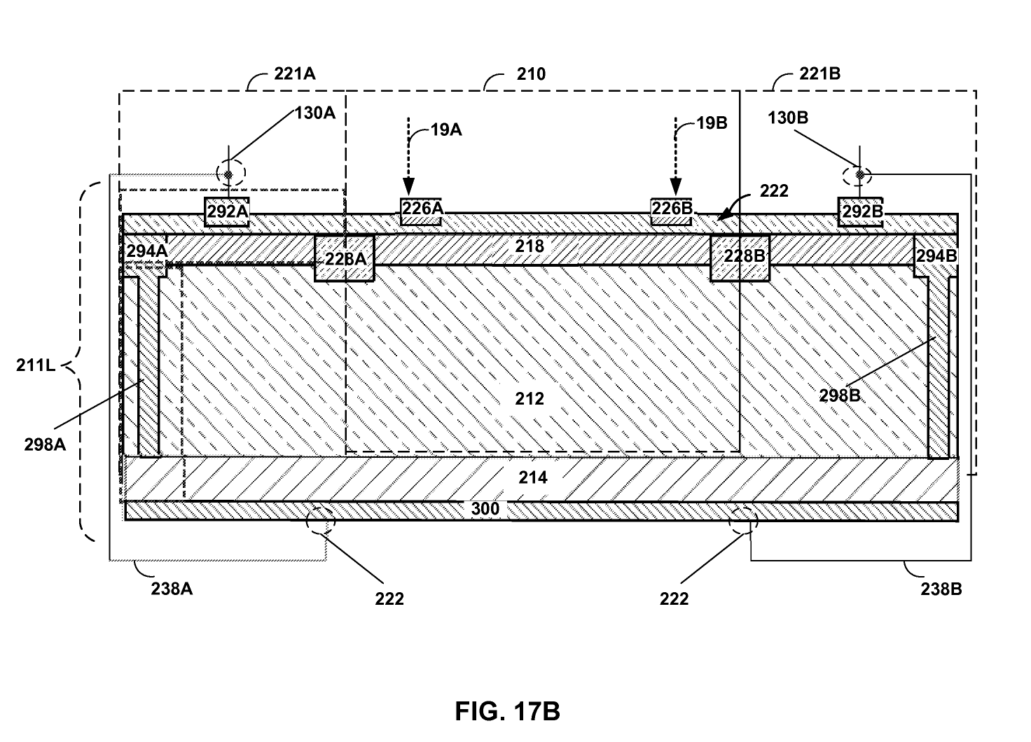

FIGS. 17A and 17B are cross sectional layered views of semiconductor dies 211K and 211L that each include an additional example of coupling structure 221A of FIG. 7A laterally integrated with AC switch 210 (e.g., bidirectional GaN based switch) that shares the same structure as AC switch 6H of FIG. 5C. In the example of FIGS. 17A and 17B, elements 230A and 230B are respective cascode type arrangements of devices that are configured as individual pn-diodes for instance, as shown in FIG. 11C. For example, a classic cascode arrangement generally includes a low-voltage field-effect-transistor (FET) and a normally-on device such as a junction-gate-field-effect-transistor (JFET) or HEMT. The classic cascode arrangement configures the low-voltage FET to operate as a common emitter or common source and the JFET or HEMT to operate as a common base or common gate. The cascode improves input-output isolation (or reverse transmission) as there is no direct coupling from the output to input. This eliminates the Miller effect and thus contributes to a much higher bandwidth. In the cascode type arrangement of FIGS. 17A and 17B, the low-voltage FET is replaced with a diode (e.g., a low voltage diode) that has similar connections with the normally-on HEMT as if the diode and HEMT were part of the classic cascode arrangement.

Semiconductor 211K is similar to semiconductor 211C of FIG. 11A and semiconductor 211G of FIG. 14A, however AC switch 210 of semiconductor 211K is a true, bidirectional switch that has only a single GaN based device like that shown in FIG. 5C. Semiconductor 211L is similar to semiconductor 211D of FIG. 11B and semiconductor 211H of FIG. 14B, however AC switch 210 of semiconductor 211K is a true, bidirectional switch that has only a single GaN based device like that shown in FIG. 5C. Source terminal 228A of AC switch 210 is also the cathode of element 230A and source terminal 228B is also the cathode of element 230B.

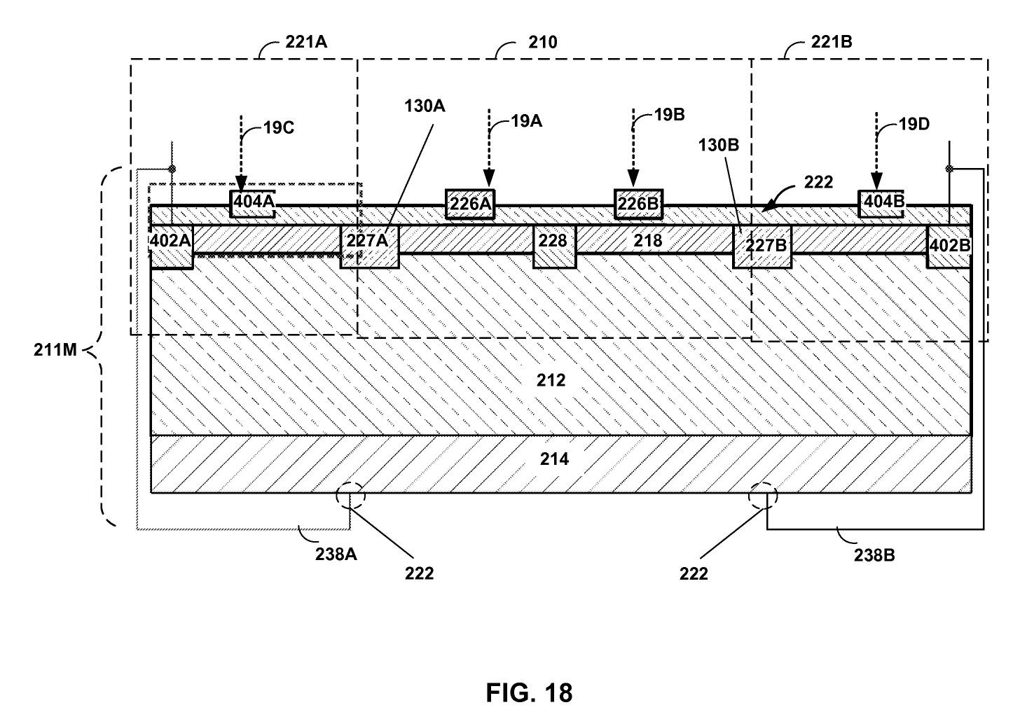

FIG. 18 is a cross sectional layered view of semiconductor die 211M that includes an example of coupling structure 221B of FIG. 7B laterally integrated with AC switch 210 (e.g., bidirectional GaN based switch) that shares the same structure as AC switch 6F of FIG. 5A. For example, FIG. 18 shows semiconductor die 211M having monolithic integrated switches (e.g., active elements 240A and 240B) arranged as part of coupling structure 221B and integrated on die 211M with AC switch 210, a common source type bidirectional switch like AC switch 6F of FIG. 5A.

AC switch 210 has load terminals 130A and 130B, which also correspond, respectively, to drain terminals 227A and 227B. AC switch 210 is a common source type bidirectional switch with source terminal 228. AC switch 210 further includes gate terminals 226A and 226B. Controller unit 5 may provide gate control signals via links 19A and 19B of link 9B to switch AC switch 210 on and off to control whether current flows between load terminals 130A and 130B within a 2DEG region (not shown) of die 211A that is adjacent to AlGaN layer 218 and GaN layer 212.

Active element 240A includes source terminal 402A, gate electrode 404A, and a drain terminal which corresponds to drain terminal 227A and load terminal 130A. Source terminal 402A is connected (e.g., by bond wire 238A) to common substrate 214. Gate electrode 404A receives a signal via link 19C (e.g., from a controller or a circuit) that is derived from the polarity of the voltage between terminals 130A and 130B. For example, when the voltage between terminals 130A and 130B is negative, gate electrode 404A may receive a signal to switch-on element 240A and couple load terminal 130A to common substrate 214. When the voltage between terminals 130A and 130B is positive, gate electrode 404A may receive a signal to switch-off element 240A and de-couple load terminal 130A from common substrate 214.

Active element 240B includes source terminal 402B, gate electrode 404B, and a drain terminal which corresponds to drain terminal 227B and load terminal 130B. Source terminal 402B is connected (e.g., by bond wire 238B) to common substrate 214. Gate electrode 404B receives a signal via link 19D (e.g., from a controller or a circuit) that is derived from the polarity of the voltage between terminals 130A and 130B. For example, when the voltage between terminals 130A and 130B is positive, gate electrode 404B may receive a signal to switch-on element 240B and couple load terminal 130B to common substrate 214. When the voltage between terminals 130A and 130B is negative, gate electrode 404B may receive a signal to switch-off element 240B and de-couple load terminal 130B from common substrate 214.

Accordingly, FIG. 18 shows that AC switch 210 (e.g., a bidirectional switch) formed at least partially within GaN layer 212 and monolithically integrated on semiconductor die 2211M, with coupling structure 221B (e.g., including elements 240A and 240B and bond wires 238A and 238B). Coupling structure 221B of semiconductor die 2111M is configured to prevent current collapse in GaN layer 212 by dynamically coupling (e.g., while AC source 2 and AC load 4 exchange energy) common substrate 214 to a lowest potential load terminal from load terminal 130A and load terminal 130B.

Controller unit 5 may determine that load terminal 130A is the lowest potential load terminal in response to determining that the voltage across load terminal 130A and load terminal 130B is greater than a threshold (e.g., zero volts). Controller unit 5 may activate element 240A so that common substrate 214 is at approximately the same potential as load terminal 130A (e.g., within a few volts but off by a voltage drop across the respective coupling structure 221A or 221B).

Controller unit 5 may determine that load terminal 130B is the lowest potential load terminal in response to determining that the voltage across load terminal 130A and load terminal 130B is less than a threshold (e.g., zero volts). Controller unit 5 may activate element 240B so that common substrate 214 is at approximately the same potential as load terminal 130B (e.g., within a few volts but off by a voltage drop across the respective coupling structure 221A or 221B).

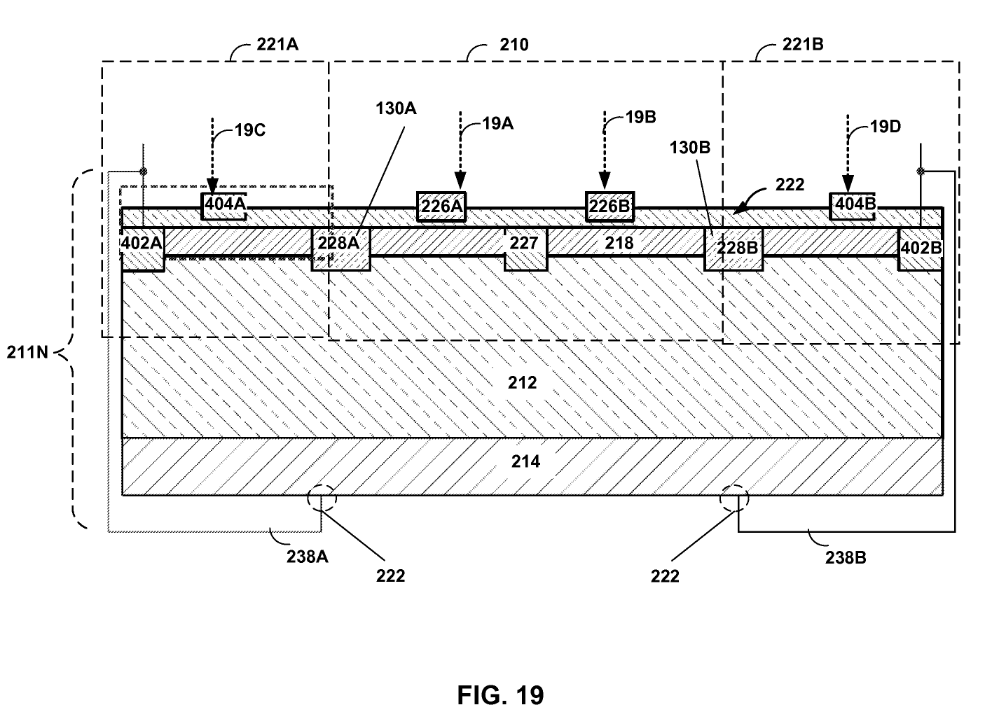

FIG. 19 is a cross sectional layered view of semiconductor die 211N that includes an additional example of the coupling structure 221B of FIG. 7B laterally integrated with AC switch 210 (e.g., bidirectional GaN based switch) that shares the same structure as AC switch 6G of FIG. 5B. For example, FIG. 19 shows semiconductor die 211N having monolithic integrated switches (e.g., active elements 240A and 240B) arranged as part of coupling structure 221B and integrated on die 211N with AC switch 210, a common drain type bidirectional switch like AC switch 6G of FIG. 5B. Semiconductor die 211N includes elements 240A and 240B laterally integrated on opposite sides of AC switch 210. In the example of FIG. 19, elements 240A and 240B are transistor type switch devices and AC switch 210 is a common drain bidirectional GaN based switch.

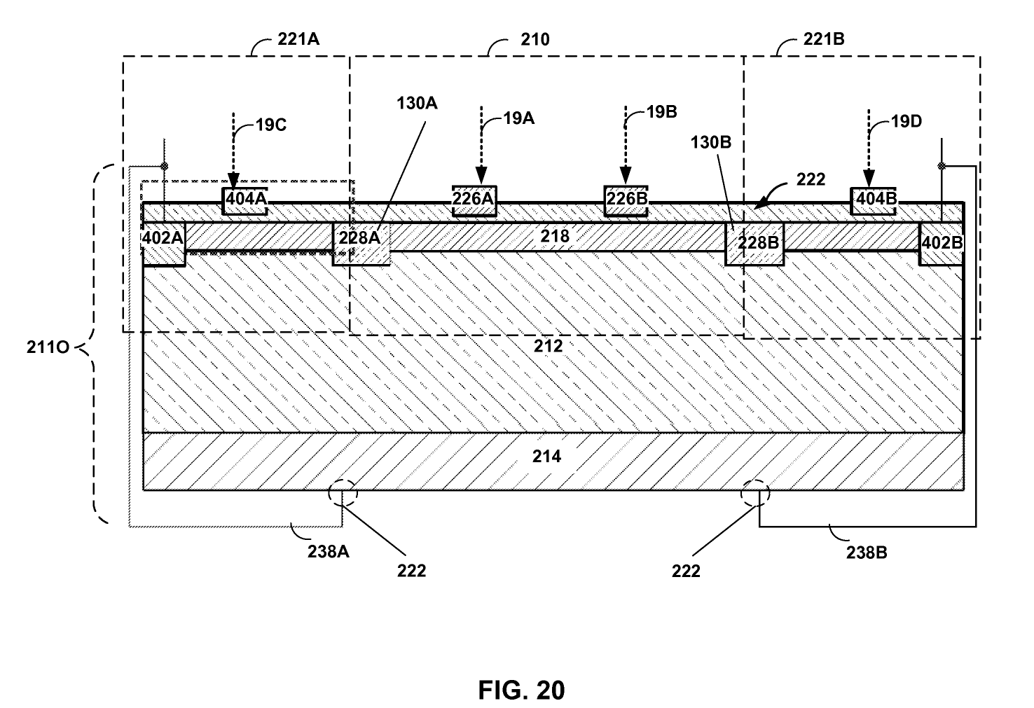

FIG. 20 is a cross sectional layered view of semiconductor die 211O that includes an additional example of the coupling structure 221B of FIG. 7B laterally integrated with AC switch 210 (e.g., bidirectional GaN based switch) that shares the same structure as AC switch 6H of FIG. 5C. Semiconductor die 211O includes elements 240A and 240B laterally integrated on opposite sides of AC switch 210. In the example of FIG. 20, elements 240A and 240B are transistor type switch devices and AC switch 210 is a true, bidirectional switch that has only a single GaN based device like that shown in FIG. 5C.

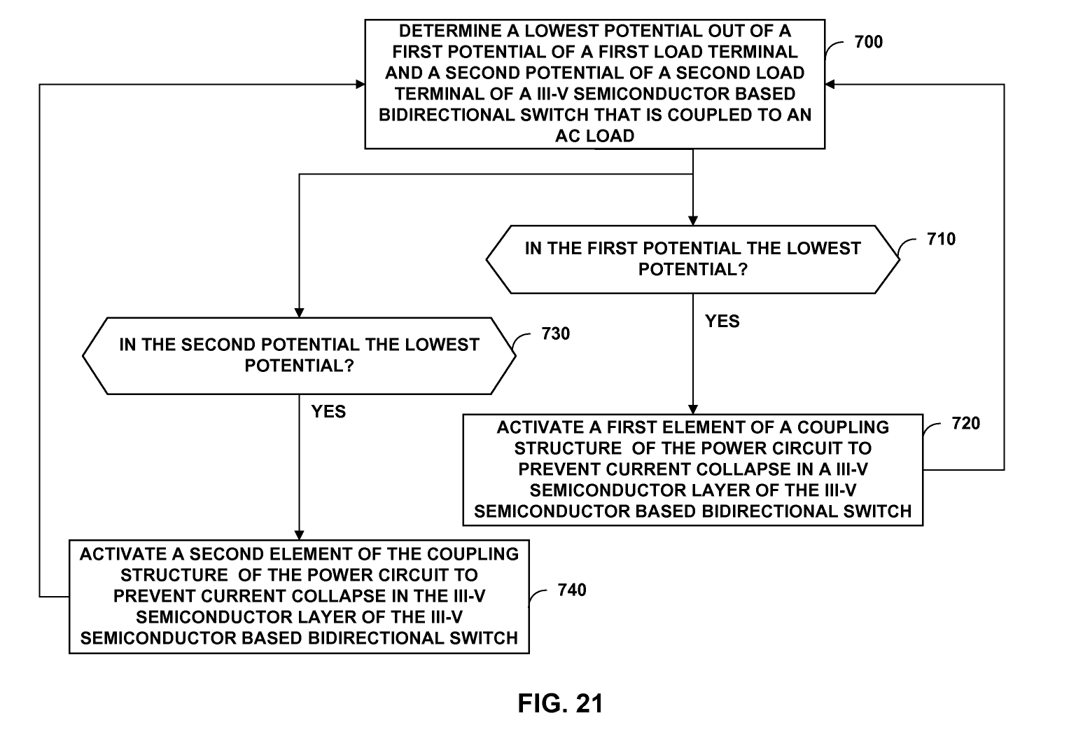

FIG. 21 is a flow chart illustrating example operations of power circuit 200B shown in FIG. 7B, in accordance with one or more aspects of the present disclosure. For example, the operations of FIG. 21 may be performed by at least one processor of controller unit 5, or at least one module of controller unit 5 that is operable by at least one processor, to control power circuit 200B of FIG. 7B while controlling the exchange of AC energy between AC source 2 and AC load 4. FIG. 21 is described below within the context of system 1A of FIG. 1.

Controller unit 5 may determine a lowest potential out of a first load terminal potential and a second load terminal potential a III-V semiconductor based bidirectional switch that is coupled to an AC load. The III-V semiconductor based bidirectional switch may be formed at least partially within a III-V semiconductor layer formed atop a common substrate of a semiconductor die (700). For example, via links 9A and 9C, controller unit 5 may receive information about the voltage level at each of load terminals 130A and 130B of AC switch 210 of power circuit 200B.

Responsive to determining that the first load terminal is at the lowest potential (710), controller unit 5 may activate a first element of a coupling structure of the power circuit to prevent current collapse in the III-V semiconductor layer (720). For example, based on the information received via links 9A and 9C about the voltage level at each of load terminals 130A and 130B of AC switch 210, controller unit 5 may determine that load terminal 130A is at a greater voltage level than load terminal 130B. Controller unit 5 may activate element 240B of power circuit 200B in order to couple substrate 212 at node 222 to load terminal 130B.

Responsive to determining that the second load terminal potential is the lowest potential (730), controller unit 5 may activate a second element of the coupling structure of the power circuit to prevent current collapse in the III-V semiconductor layer (740). For example, based on the information received via links 9A and 9C about the voltage level at each of load terminals 130A and 130B of AC switch 210, controller unit 5 may determine that load terminal 130B is at a greater voltage level than load terminal 130A. Controller unit 5 may activate element 240A of power circuit 200B in order to couple substrate 212 at node 222 to load terminal 130A.

In some examples, controller unit 5 may activate the first element of the coupling structure by at least activating a first transistor-type switch of the coupling structure to electrically couple the common substrate to the first load terminal and controller unit 5 may activate the second element of the coupling structure by at least activating a second transistor type switch of the coupling structure to electrically couple the common substrate to the second load terminal. For example, controller unit 5 may cause a transistor type switch of element 240A to operate in a switched-on state when controller unit 5 determines that load terminal 130A is at a lower potential than load terminal 130B. Conversely, controller unit 5 may cause a transistor type switch of element 240B to operate in a switched-on state when controller unit 5 determines that load terminal 130B is at a lower potential than load terminal 130A.

In some examples, responsive to determining that the first load terminal is the lowest potential load terminal, controller unit 5 may de-activate the second element of the coupling structure to de-couple the common substrate from the second load terminal, and responsive to determining that the second load terminal is the lowest potential load terminal, controller unit 5 may de-activate the first element of the coupling structure to de-couple the common substrate from the first load terminal. For example, controller unit 5 may cause a transistor type switch of element 240B to operate in a switched-off state when controller unit 5 determines that load terminal 130A is at a lower potential than load terminal 130B. Conversely, controller unit 5 may cause a transistor type switch of element 240A to operate in a switched-off state when controller unit 5 determines that load terminal 130B is at a lower potential than load terminal 130A.

Clause 1. A power circuit comprising: a semiconductor die that includes a common substrate and a III-V semiconductor layer formed atop the common substrate, wherein: at least one bidirectional switch device is formed at least partially within the III-V semiconductor layer, and the at least one bidirectional switch comprises at least a first load terminal and a second load terminal; and a coupling structure configured to dynamically couple the common substrate of the semiconductor die to a lowest potential out of a first potential of the first load terminal and a second potential of the second load terminal.

Clause 2. The power circuit of clause 1, wherein the III-V semiconductor layer comprises a III-V semiconductor material, wherein III-V semiconductor material is selected from a group consisting of: Boron Nitride (BN), Boron Phosphide (BP), Boron Arsenide (BAs), Aluminum Nitride (AlN), Aluminum Phosphide (AlP), Aluminum Arsenide (AlAs), Aluminum Antimonide (AlSb), Gallium Nitride (GaN), Gallium Phosphide (GaP), Gallium Arsenide (GaAs), Gallium Antimonide (GaSb), Indium Nitride (InN), Indium Phosphide (InP), Indium Arsenide (InAs), Indium Antimonide (InSb), Titanium Nitride (TiN), Titanium Phosphide (TiP), Titanium Arsenide (TiAs), and Titanium Antimonide (TiSb).

Clause 3. The power circuit of any of clauses 1-2, wherein the coupling structure is further configured to prevent current collapse in the III-V semiconductor layer by dynamically coupling the common substrate of the semiconductor die to the lowest potential.

Clause 4. The power circuit of any of clauses 1-3, wherein: the coupling structure comprises a first element arranged between the common substrate and the first load terminal and a second element arranged between the common substrate and the second load terminal, the first element is configured to electrically couple the common substrate to the first load terminal in response to a voltage across the first and second load terminals being greater than a threshold, and the second element is configured to electrically couple the common substrate to the second load terminal in response to the voltage across the first and second load terminals being less than the threshold.

Clause 5. The power circuit of clause 4, wherein the first and second elements each comprise a respective transistor based switch.

Clause 6. The power circuit any of clauses 4-5, wherein the first and second elements each comprise a respective diode.

Clause 7. The power circuit of clause 6, wherein the respective diode of each of the first and second elements is a Schottky diode.

Clause 8. The power circuit of any of clauses 6-7, wherein the respective diode of each of the first and second elements is a respective cascode type arrangement of a low voltage diode and a lateral high electron mobility transistor.

Clause 9. The power circuit any of clauses 1-9, further comprising: a control unit configured to control the coupling structure to dynamically couple the common substrate of the semiconductor die to the lowest potential out of the first potential and the second potential.

Clause 10. The power circuit of clause 9, wherein the control unit is further configured to: determine that the first load terminal is the lowest potential load terminal in response to determining that a voltage across the first load terminal and the second load terminal is greater than a threshold; and determine that the second load terminal is the lowest potential load terminal in response to determining the voltage across the first load terminal and the second load terminal is less than the threshold.

Clause 11. The power circuit of any of clauses 9-10, wherein the control unit is further configured to: determine that the first load terminal is the lowest potential load terminal in response to determining that a voltage across the first potential is less than the second potential; and determine that the second load terminal is the lowest potential load terminal in response to determining the second potential is less than the first potential.

Clause 12. A semiconductor die comprising: a common substrate; a III-V semiconductor layer formed atop the common substrate; a bidirectional switch device formed at least partially within the III-V semiconductor layer, the bidirectional switch device having at least a first load terminal and a second load terminal; and a coupling structure configured to dynamically couple the common substrate to a lowest potential out of a first potential of the first load terminal and a second potential of the second load terminal.

Clause 13. The semiconductor die of clause 12, wherein: the coupling structure comprises a first element arranged between the common substrate and the first load terminal and a second element arranged between the common substrate and the second load terminal, the first element is configured to electrically couple the common substrate to the first load terminal in response to the first potential being less than the second potential, and the second element is configured to electrically couple the common substrate to the second load terminal in response to second potential being less than the first potential.

Clause 14. The semiconductor die of clause 13, wherein the first and second elements each comprise a respective transistor based switch formed at least partially within the GaN layer.

Clause 15. The semiconductor die of any of clauses 13-14, wherein the first and second elements each comprise a respective diode.

Clause 16. The semiconductor die of clause 15, wherein the respective diode of each of the first and second elements is a Schottky diode.

Clause 17. The semiconductor die of any of clauses 15-16, wherein the respective diode of each of the first and second elements is a respective cascode type arrangement of a low voltage diode and a lateral high electron mobility transistor.

Clause 18. The semiconductor die of any of clauses 12-17, wherein the bidirectional switch device comprises a first III-V semiconductor based device for blocking a positive current at the first load terminal when switched-off and a second III-V semiconductor based switch device for blocking a negative current at the second load terminal when switched-off.

Clause 19. The semiconductor die of any of clauses 12-18, wherein the III-V semiconductor layer is a first III-V semiconductor layer, the semiconductor die further comprising a second III-V semiconductor layer formed atop the common substrate, wherein the bidirectional switch device comprises a first III-V semiconductor based switch device formed at least partially within the first III-V semiconductor layer and a second III-V semiconductor based switch device formed at least partially within the second III-V semiconductor layer.

Clause 20. The semiconductor die of any of clauses 12-19, wherein the bidirectional switch device comprises a first III-V semiconductor based switch device and a second III-V semiconductor based switch device, and wherein: the first III-V semiconductor based switch device and the second III-V semiconductor based switch device share a common source, the first III-V semiconductor based switch device and the second III-V semiconductor based switch device share a common drain terminal, or the first III-V semiconductor based switch device and the second III-V semiconductor based switch device share a common drift region.

Clause 21. A method comprising: operating a semiconductor die that includes a common substrate and a III-V semiconductor layer formed atop the common substrate, wherein at least one bidirectional switch device is formed at least partially within the III-V semiconductor layer, the at least one bidirectional switch having at least a first load terminal and a second load terminal; and dynamically coupling the common substrate of the semiconductor die to a lowest potential out of a first potential of the first load terminal and a second potential of the second load terminal.

Clause 22. The method of clause 21, wherein dynamically coupling the common substrate prevents current collapse in the III-V semiconductor layer.

Clause 23. The method of any of clauses 21-22, further comprising: determining, by a control unit of a power circuit, the lowest potential; responsive to determining that the first potential is the lowest potential, activating, by the control unit, a first element of a coupling structure of the power circuit that dynamically couples the common substrate of the semiconductor die to the first potential; and responsive to determining that the second load terminal is the lowest potential load terminal, activating, by the control unit, a second element of the coupling structure of the power circuit that dynamically couples the common substrate of the semiconductor die to the second potential.

Clause 24. The method of any of clauses 21-23, wherein: activating the first element of the coupling structure comprises activating a first transistor type switch of the first element to electrically couple the common substrate to the first potential; activating the second element of the coupling structure comprises activating a second transistor type switch of the second element to electrically couple the common substrate to the second potential.

Clause 25. The method of any of clauses 21-24, further comprising: responsive to determining that the first potential is the lowest potential, de-activating the second element of the coupling structure to de-couple the common substrate from the second potential; and responsive to determining that the second potential is the lowest potential, de-activating the first element of the coupling structure to de-couple the common substrate from the first potential.

Clause 26. A power circuit comprising means for performing any of the methods of clauses 21-25.

Clause 27. The power circuit of any of clauses 1-11 comprising means for performing any of the methods of clauses 21-25.

Clause 28. A computer readable storage medium comprising instructions that when executed configure at least one processor to perform any of the methods of clauses 21-25.

Clause 29. A power circuit comprising: the semiconductor die of any of clauses 12-20; and means for performing any of the methods of clauses 21-25.

In one or more examples, the functions described may be implemented in hardware, software, firmware, or any combination thereof. For example, controller unit 5 of FIGS. 1-3 may include at least one processor, memory, or any other suitable arrangement of software, firmware, and hardware to implement the techniques of this disclosure. If implemented in software, the functions may be stored on or transmitted over, as one or more instructions or code, a computer-readable medium and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media, which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

By way of example, and not limitation, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transient media, but are instead directed to non-transient, tangible storage media. Disk and disc, as used herein, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor,” as used herein may refer to any of the foregoing structure or any other structure suitable for implementation of the techniques described herein. In addition, in some aspects, the functionality described herein may be provided within dedicated hardware and/or software modules. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a hardware unit or provided by a collection of interoperative hardware units, including one or more processors as described above, in conjunction with suitable software and/or firmware.

Various examples have been described. Many of the described examples concern techniques for communicating between the secondary and primary side of a flyback converter so as to enable the use of a common controller for both sides of the flyback converter. However, the described techniques for communicating between two sides of a transformer may also be used for other reasons, or in other transformer applications. These and other examples are within the scope of the following claims.

1. A power circuit comprising:
a semiconductor die that includes a common substrate and a III-V semiconductor layer formed atop the common substrate, wherein:
at least one bidirectional switch device is formed at least partially within the III-V semiconductor layer, and
the at least one bidirectional switch comprises at least a first load terminal and a second load terminal; and
a coupling structure configured to dynamically couple the common substrate of the semiconductor die to a lowest potential out of a first potential of the first load terminal and a second potential of the second load terminal.

2. The power circuit of claim 1, wherein the III-V semiconductor layer comprises a III-V semiconductor material, wherein III-V semiconductor material is selected from a group consisting of: Boron Nitride (BN), Boron Phosphide (BP), Boron Arsenide (BAs), Aluminum Nitride (AlN), Aluminum Phosphide (AlP), Aluminum Arsenide (AlAs), Aluminum Antimonide (AlSb), Gallium Nitride (GaN), Gallium Phosphide (GaP), Gallium Arsenide (GaAs), Gallium Antimonide (GaSb), Indium Nitride (InN), Indium Phosphide (InP), Indium Arsenide (InAs), Indium Antimonide (InSb), Titanium Nitride (TiN), Titanium Phosphide (TiP), Titanium Arsenide (TiAs), and Titanium Antimonide (TiSb).

3. The power circuit of claim 1, wherein the coupling structure is further configured to prevent current collapse in the III-V semiconductor layer by dynamically coupling the common substrate of the semiconductor die to the lowest potential.

4. The power circuit of claim 1, wherein:
the coupling structure comprises a first element arranged between the common substrate and the first load terminal and a second element arranged between the common substrate and the second load terminal,
the first element is configured to electrically couple the common substrate to the first load terminal in response to a voltage across the first and second load terminals being greater than a threshold, and
the second element is configured to electrically couple the common substrate to the second load terminal in response to the voltage across the first and second load terminals being less than the threshold.

5. The power circuit of claim 4, wherein the first and second elements each comprise a respective transistor based switch.

6. The power circuit of claim 4, wherein the first and second elements each comprise a respective diode.

7. The power circuit of claim 6, wherein the respective diode of each of the first and second elements is a Schottky diode.

8. The power circuit of claim 6, wherein the respective diode of each of the first and second elements is a respective cascode type arrangement of a low voltage diode and a lateral high electron mobility transistor.

9. The power circuit of claim 1, further comprising:
a control unit configured to control the coupling structure to dynamically couple the common substrate of the semiconductor die to the lowest potential out of the first potential and the second potential.

10. The power circuit of claim 9, wherein the control unit is further configured to:
determine that the first load terminal is the lowest potential load terminal in response to determining that a voltage across the first load terminal and the second load terminal is greater than a threshold; and
determine that the second load terminal is the lowest potential load terminal in response to determining the voltage across the first load terminal and the second load terminal is less than the threshold.

11. The power circuit of claim 9, wherein the control unit is further configured to:
determine that the first load terminal is the lowest potential load terminal in response to determining that a voltage across the first potential is less than the second potential; and
determine that the second load terminal is the lowest potential load terminal in response to determining the second potential is less than the first potential.

12. A semiconductor die comprising:
a common substrate;
a III-V semiconductor layer formed atop the common substrate;
a bidirectional switch device formed at least partially within the III-V semiconductor layer, the bidirectional switch device having at least a first load terminal and a second load terminal; and
a coupling structure configured to dynamically couple the common substrate to a lowest potential out of a first potential of the first load terminal and a second potential of the second load terminal.

13. The semiconductor die of claim 12, wherein:
the coupling structure comprises a first element arranged between the common substrate and the first load terminal and a second element arranged between the common substrate and the second load terminal,
the first element is configured to electrically couple the common substrate to the first load terminal in response to the first potential being less than the second potential, and
the second element is configured to electrically couple the common substrate to the second load terminal in response to second potential being less than the first potential.

14. The semiconductor die of claim 13, wherein the first and second elements each comprise a respective transistor based switch formed at least partially within the GaN layer.

15. The semiconductor die of claim 13, wherein the first and second elements each comprise a respective diode.

16. The semiconductor die of claim 15, wherein the respective diode of each of the first and second elements is a Schottky diode.

17. The semiconductor die of claim 15, wherein the respective diode of each of the first and second elements is a respective cascode type arrangement of a low voltage diode and a lateral high electron mobility transistor.

18. The semiconductor die of claim 12, wherein the bidirectional switch device comprises a first III-V semiconductor based device for blocking a positive current at the first load terminal when switched-off and a second III-V semiconductor based switch device for blocking a negative current at the second load terminal when switched-off.

19. The semiconductor die of claim 12, wherein the III-V semiconductor layer is a first III-V semiconductor layer, the semiconductor die further comprising a second III-V semiconductor layer formed atop the common substrate, wherein the bidirectional switch device comprises a first III-V semiconductor based switch device formed at least partially within the first III-V semiconductor layer and a second III-V semiconductor based switch device formed at least partially within the second III-V semiconductor layer.

20. The semiconductor die of claim 12, wherein the bidirectional switch device comprises a first III-V semiconductor based switch device and a second III-V semiconductor based switch device, and wherein:
the first III-V semiconductor based switch device and the second III-V semiconductor based switch device share a common source,
the first III-V semiconductor based switch device and the second III-V semiconductor based switch device share a common drain terminal, or
the first III-V semiconductor based switch device and the second III-V semiconductor based switch device share a common drift region.

21. A method comprising:
operating a semiconductor die that includes a common substrate and a III-V semiconductor layer formed atop the common substrate, wherein at least one bidirectional switch device is formed at least partially within the III-V semiconductor layer, the at least one bidirectional switch having at least a first load terminal and a second load terminal; and
dynamically coupling the common substrate of the semiconductor die to a lowest potential out of a first potential of the first load terminal and a second potential of the second load terminal.

22. The method of claim 21, wherein dynamically coupling the common substrate prevents current collapse in the III-V semiconductor layer.

23. The method of claim 21, further comprising:
determining, by a control unit of a power circuit, the lowest potential;
responsive to determining that the first potential is the lowest potential, activating, by the control unit, a first element of a coupling structure of the power circuit that dynamically couples the common substrate of the semiconductor die to the first potential; and
responsive to determining that the second load terminal is the lowest potential load terminal, activating, by the control unit, a second element of the coupling structure of the power circuit that dynamically couples the common substrate of the semiconductor die to the second potential.

24. The method of claim 21, wherein:
activating the first element of the coupling structure comprises activating a first transistor type switch of the first element to electrically couple the common substrate to the first potential;
activating the second element of the coupling structure comprises activating a second transistor type switch of the second element to electrically couple the common substrate to the second potential.

25. The method of claim 21, further comprising:
responsive to determining that the first potential is the lowest potential, de-activating the second element of the coupling structure to de-couple the common substrate from the second potential; and
responsive to determining that the second potential is the lowest potential, de-activating the first element of the coupling structure to de-couple the common substrate from the first potential.
